(19) United States
(12) Patent Application Publication
(10) Pub. No.: US 2025/0199640 A1
(43) Pub. Date: Jun. 19, 2025

(54) SEMICONDUCTOR MODULE AND DISPLAY DEVICE

(71) Applicant: Samsung Electronics Co., Ltd., Suwon-si (KR)

(72) Inventors: JINBONG KIM, Suwon-si (KR); Yunrae Jo, Suwon-si (KR); Woo-Nyoung Lee, Suwon-si (KR)

(73) Assignee: Samsung Electronics Co., Ltd., Suwon-si (KR)

(21) Appl. No.: 18/903,673

(22) Filed: Oct. 1, 2024

(30) Foreign Application Priority Data
Dec. 19, 2023 (KR) 10-2023-0185968

(51) Int. Cl. G06F 3/041; G06F 3/044; G09G 3/3275

(52) U.S. Cl. CPC G06F 3/0418; G06F 3/0412; G06F 3/04164; G06F 3/0446; G06F 2203/04107; G09G 3/3275; G09G 2330/028; G09G 2354/00

(57) ABSTRACT

A semiconductor device includes: a display driver circuit configured to drive a display panel; a touch sensor controller configured to generate touch coordinates based on an input on a touch screen panel, the touch sensor controller includes: a first transmitter and receiver set on a first side of the display driver circuit; and a second transmitter and receiver set on a second side of the display driver circuit, the second side being opposite the first side. The semiconductor device further includes a plurality of routing lines connecting the touch sensor controller and the touch screen panel.

### CROSS-REFERENCE TO RELATED APPLICATION

This application claims priority to Korean Patent Application No. 10-2023-0185968, filed on Dec. 19, 2023, in the Korean Intellectual Property Office, the disclosure of which is incorporated by reference herein in its entirety.

### BACKGROUND

### 1. Field

The present disclosure relates to a semiconductor module and a display device.

### 2. Description of Related Art

A touch screen includes a display panel for image display and a touch sensor for touch sensing, and the display panel and the touch sensor may be vertically stacked, or may be integrally formed so as to share at least one layer.

With the trend toward ultra-slim touch screens, the distances between display panels and touch sensors have decreased. Accordingly, the parasitic capacitance between display panels and electrodes of touch sensors may increase, and display noise which occurs during displaying may be introduced into touch sensors by the parasitic capacitance. The display noise may reduce the touch sensing sensitivity. Various methods for reducing such noise have been researched.

### SUMMARY

Example embodiments provide a semiconductor module and a display device that may be capable of improving touch sensing sensitivity.

According to an aspect of an example embodiment, a semiconductor device may include: a display driver circuit configured to drive a display panel; a touch sensor controller configured to generate touch coordinates based on an input on a touch screen panel, the touch sensor controller may include: a first transmitter and receiver set on a first side of the display driver circuit; and a second transmitter and receiver set which is on a second side of the display driver circuit, the second side being opposite the first side. The semiconductor device may further include a plurality of routing lines connecting the touch sensor controller and the touch screen panel.

According to an aspect of an example embodiment, a semiconductor device may include: a display driver circuit configured to drive a display panel; a touch sensor controller configured to generate touch coordinates based on an input on a touch screen panel, and may include: first receivers and second receivers on both sides of the display driver circuit, respectively; and transmitters on one side of the display driver circuit. The semiconductor device may further include a plurality of routing lines that connects the touch sensor controller and the touch screen panel.

According to an aspect of an example embodiment, a display device may include: a display panel may include a plurality of pixels and a plurality of source lines connected to the plurality of pixels; a plurality of first direction touch electrodes and a plurality of second direction touch electrodes; a plurality of routing lines connected to the plurality of first direction touch electrodes and the plurality of second direction touch electrodes; and a touch screen driver circuit may include: a display driver circuit on a center region of the touch screen driver circuit, and configured to apply a plurality of source signals to the plurality of source lines; and a transmitter and receiver set on a periphery of the center region and connected to the plurality of routing lines.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a block diagram of a touch screen device according to one or more embodiments;

FIG. 2 shows an example of a touch sensor according to one or more embodiments;

FIG. 3 shows an example of a touch sensor according to one or more embodiments;

FIG. 4 shows the operation of a touch screen device according to one or more embodiments;

FIG. 5 shows the operation of a display module according to one or more embodiments;

FIG. 6 shows routing of display modules according to one or more embodiments;

FIG. 7 shows routing of display modules according to one or more embodiments;

FIG. 8 shows routing of display modules according to one or more embodiments;

FIG. 9 shows routing of display modules according to one or more embodiments;

FIG. 10 shows routing of display modules according to one or more embodiments;

FIG. 11 shows routing of display modules according to one or more embodiments;

FIG. 12 shows routing of display modules according to one or more embodiments;

FIG. 13 shows routing of display modules according to one or more embodiments;

FIG. 14 shows routing of display modules according to one or more embodiments;

FIG. 15 shows routing of display modules according to one or more embodiments;

FIG. 16 shows routing of display modules according to one or more embodiments;

FIG. 17 shows routing of display modules according to one or more embodiments;

FIG. 18 shows routing of display modules according to one or more embodiments;

FIG. 19 shows routing of display modules according to one or more embodiments;

FIG. 20 shows routing of display modules according to one or more embodiments;

FIG. 21 shows routing of display modules according to one or more embodiments;

FIG. 22 shows routing of display modules according to one or more embodiments;

FIG. 23 is the flow chart of a method of manufacturing a display module according to one or more embodiments; and

FIG. 24 is a block diagram of an electronic device according to one or more embodiments.

### DETAILED DESCRIPTION

In the following detailed description, only certain embodiments have been shown and described, simply by way of illustration. As those skilled in the art would realize, the described embodiments may be modified in various different ways, all without departing from the spirit or scope of the disclosure.

Accordingly, the drawings and description are to be regarded as illustrative in nature and not restrictive. Like reference numerals designate like elements throughout the specification. In the flow charts described with reference to the drawings, the order of operations may be changed, and several operations may be combined, and an operation may be divided, and some operations may not be performed.

Further, expressions written in the singular forms can be comprehended as the singular forms or plural forms unless clear expressions such as “a”, “an”, or “single” are used. Terms including an ordinal number, such as first and second, are used for describing various constituent elements, but the constituent elements are not limited by the terms. The terms are used only to discriminate one constituent element from other constituent elements.

Elements described as “modules” or “part” may be physically implemented by analog and/or digital circuits including one or more of a logic gate, an integrated circuit, a microprocessor, a microcontroller, a memory circuit, a passive electronic component, an active electronic component, and the like.

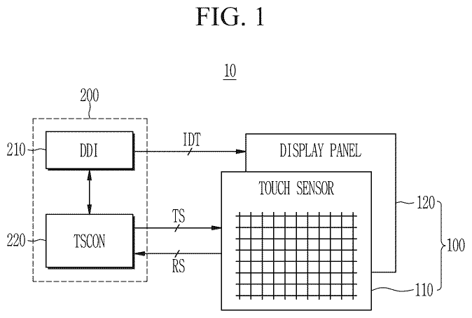

FIG. 1 is a block diagram of a touch screen device according to one or more embodiments.

Referring to FIG. 1, a touch screen device 10 according to one or more embodiments may be mounted in various electronic devices. For example, the touch screen device 10 may be mounted in electronic devices such as personal computers (PCs), tablet PCs, e-readers or e-book readers, personal digital assistants (PDAs), portable multimedia players (PMPs), digital cameras, portable game consoles, monitors, TV sets, mobile terminals, smart phones, wearable devices, Internet of things (IoT) devices, electronic blackboards, refrigerators, navigation devices, etc. Also, the touch screen device 10 may be mounted in electronic devices that are provided as components in vehicles, furniture, manufacturing equipment, doors, various measurement devices, and the like.

The touch screen device 10 may include a touch display 100, and a touch screen driver circuit 200 for driving the touch display 100. The touch display 100 may include a touch sensor (or a touch screen panel) 110 and a display panel 120, and may provide a touch sensing function and a display function. The touch screen driver circuit 200 may include a display driver circuit (DDI) 210 and a touch sensor controller (TSCON) 220. The display driver circuit 210 and the touch sensor controller 220 may be integrated into a single semiconductor chip, or may be implemented separately in a plurality of semiconductor chips. Alternatively, the display driver circuit 210 and the touch sensor controller 220 may be implemented as a single semiconductor module.

The touch display 100 may display images, and may receive touch inputs from a user. The touch display 100 may serve as an input/output device for an electronic device, and may serve as a proximity sensor for sensing an approach of conductive objects. In some embodiments, the touch display 100 may further include a fingerprint sensor, and the touch screen device 10 may perform a fingerprint recognition function.

The touch sensor 110 may sense touches (or touch inputs) on the touch display 100, and output sensing signals. In this case, the touch sensor 110 may sense an approach of conductive objects to the touch display 100, as well as direct contact of conductive objects with the touch display 100. Examples of conductive objects include a user's body (e.g., skin such as fingers, palms, face, ears, etc.), touch pens, stylus pens, and the like. The touch sensor 110 may be disposed on the display panel 120, and may be attached to the front surface of the display panel 120 (for example, the surface from which optical signals are emitted). In some embodiments, the touch sensor 110 may cover the front surface of the display panel 120.

The touch sensor 110 may be implemented as a transparent panel having a touch-sensitive surface. Alternatively, the touch sensor 110 may be implemented as a touch sensor array including transparent external electrodes formed by patterning.

The touch sensor 110 may include a plurality of external electrodes. Through the plurality of external electrodes, sensing signals according to one of various touch sensing methods may be output. As an example, the plurality of external electrodes may output sensing signals according to capacitance sensing.

The touch sensor 110 may include driving electrodes to which driving signals TS are applied, and receiving electrodes from which sensing signals RS are output. The driving electrodes and the receiving electrodes may be disposed so as to extend in different directions. For example, the driving electrodes may extend in a first direction, and the receiving electrodes may extend in a second direction intersecting the first direction. In the embodiment, the first direction may be a longitudinal direction and the second direction may be a transverse direction orthogonal to the longitudinal direction; however, the embodiment is not necessarily limited thereto. The driving electrodes and the receiving electrodes may be referred to as driving channels and receiving channels, respectively. The touch sensor 110 may include a plurality of driving electrodes arranged side by side and a plurality of receiving electrodes arranged side by side.

The driving electrodes and the receiving electrodes may intersect each other, and between the driving electrodes and the receiving electrodes intersecting each other, mutual capacitance may be formed. The individual points where mutual capacitance is formed may be referred to as sensing nodes of the touch sensor 110.

As another example, the touch sensor 110 may include a plurality of sensing electrodes arranged in a matrix, and capacitance may be formed at each of the plurality of sensing electrodes. For example, between each of the plurality of sensing electrodes and a ground (or a conductive layer in the touch display 100), capacitance may be formed, and the capacitance may be referred to as self-capacitance. A driving signal TS may be applied to each of the plurality of sensing electrodes, and a sensing signal RS may be output from each of the plurality of sensing electrodes. In other words, each of the plurality of sensing electrodes may serve as a driving electrode and a receiving electrode, and each of the plurality of sensing electrodes may be referred to as a sensing node of the touch sensor 110.

A driving signal TS may be applied to the driving electrodes, and sensing signals RS indicating capacitance (for example, mutual capacitance or self-capacitance) may be generated in response to the driving signal TS, and the sensing signals RS may be output through the receiving electrodes. When a conductive object such as human skin (for example, a finger) or a stylus touches or approaches a sensing node of the touch sensor 110, the capacitance corresponding to the sensing node may change, and a sensing signal RS to be output from the touch sensor 110 may change in response to the changed capacitance. For example, the level of the sensing signal RS may increase or decrease as compared to before the occurrence of the touch. Based on the level of the sensing signal RS that is output from the touch sensor 110, touch data may be generated.

The display panel 120 may include a plurality of gate lines, a plurality of source lines, and a plurality of pixels arranged in a matrix at the intersections of the plurality of gate lines and the plurality of source lines. The plurality of pixels may display an image based on image data IDT received through the plurality of source lines and the plurality of gate lines. The image may be updated at a set frame rate.

The display panel 120 may be an organic light emitting diode (OLED) display. However, the embodiment is not necessarily limited thereto, and the display panel 120 may be implemented as one of a liquid crystal display (LCD), a light emitting diode (LED) display, an active-matrix OLED (AMOLED) display, an electrochromic display (ECD), a digital mirror device (DMD), an actuated mirror device (AMD), a grating light valve (GLV), a plasma display panel (PDP), an electro-luminescent display (ELD), a vacuum fluorescent display (VFD), and may be implemented as any other type of flat panel or flexible panel.

In FIG. 1, it is shown that the touch sensor 110 and the display panel 120 are separate components; however, the embodiment is not necessarily limited thereto. For example, the touch display 100 may be implemented as an in-cell type panel in which the electrodes of the touch sensor 110 and the pixels of the display panel 120 are combined or an on-cell type panel in which the electrodes of the touch sensor 110 are disposed on the display panel 120.

The touch sensor controller 220 may perform scanning (for example, driving and sensing) on the touch sensor 110. In other words, the touch sensor controller 220 may perform touch sensing. The touch sensor controller 220 may provide a driving signal TS to the driving electrodes of the touch sensor 110, and may receive a sensing signal RS, generated on the basis of the driving signal TS, from the touch sensor 110.

The display driver circuit 210 may generate image data IDT and transmit the image data to the display panel 120. The plurality of pixels of the display panel 120 may display an image based on the image data IDT. The display driver circuit 210 may receive an input image signal from a host that controls the touch screen device 10, and generate image data IDT based on the input image signal. The touch screen driver circuit 200 may operate in response to instructions of the host, and exchange data with the host.

In some embodiments, the host may include an application processor (AP), and the application processor (AP) may be implemented as a system-on-chip (SoC). The system-on-chip (SoC) may include a system bus (not shown in the drawings) according to a protocol having a predetermined standard bus specification, and may include various intellectual property (IP) blocks that are connected to the system bus. As the standard specification for the system bus, various types of specifications such as the advanced microcontroller bus architecture (AMBA) protocol of Advanced RISC Machines (ARM) Ltd., may be applied.

In the embodiment, the touch screen driver circuit 200 may be implemented as a single semiconductor module including the display driver circuit 210 and the touch sensor controller 220. In the touch screen driver circuit 200, the display driver circuit 210 may be disposed in the center, and the touch sensor controller 220 may be disposed at the periphery of the display driver circuit 210. By dispersedly disposing the touch sensor controller 220 at the periphery of the display driver circuit 210, the die height of the touch screen driver circuit 200 may be lowered. Accordingly, the number of dies that can be obtained per wafer may increase. The touch sensor controller 220 may be disposed symmetrically with respect to the display driver circuit 210; however, the embodiment is not necessarily limited thereto. In some embodiments, the touch display 100 and the touch screen driver circuit 200 may be implemented as a single semiconductor module.

Further, to connect the touch sensor 110 and the touch sensor controller 220, various routing schemes may be applied. A transmitter of the touch sensor controller 220 and the driving electrodes of the touch sensor 110 may be connected through transmission lines, and a receiver of the touch sensor controller 220 and the receiving electrodes of the touch sensor 110 may be connected through reception lines.

In the embodiment, the transmission lines may be implemented by single routing or dual routing. When the transmission lines are implemented by single routing, the chip size may be reduced. When the transmission lines are implemented by dual routing, the resistance may be reduced, so the time constant may be reduced and the settling time may be reduced.

In the embodiment, the reception lines may be connected to a receiver disposed on one side at the periphery of the display driver circuit 210, or receivers disposed on both sides at the periphery of the display driver circuit. When the reception lines are connected to a receiver disposed on one side, the chip size may be reduced. When the reception lines are connected to receivers disposed on both sides, the deviation between the channels may be reduced, so highly reliable touch data may be generated.

The touch sensor controller 220 may convert touch signals which are analog signals into touch values which are digital signals, and generate touch data including touch values corresponding to the individual sensing nodes of the touch sensor 110.

The touch sensor controller 220 may determine that a touch input has occurred at one or more specific positions on the touch display 100, on the basis of the touch data, and calculate the positions where the touch input has occurred (i.e., touch coordinates). The touch sensor controller 220 may transmit the touch coordinates to the host. In some embodiments, the host may be included in the touch screen device 10. In some embodiments, the touch sensor controller 220 may calculate a touch input, and provide the touch input along with the touch coordinates to the host.

In some embodiments, the touch sensor controller 220 may receive voltage changes at a plurality of points on the display panel 120 or offset values calculated on the basis of the voltage changes, which cause display noise at the touch sensor 110, as compensation information from the display driver circuit 210, and remove display noise from touch data or discard touch data, on the basis of the compensation information.

In this way, the touch sensor controller 220 may remove noise from sensing signals RS or process touch data on the basis of noise data. Accordingly, the reliability of the touch data can be improved, and the touch sensing sensitivity can be improved.

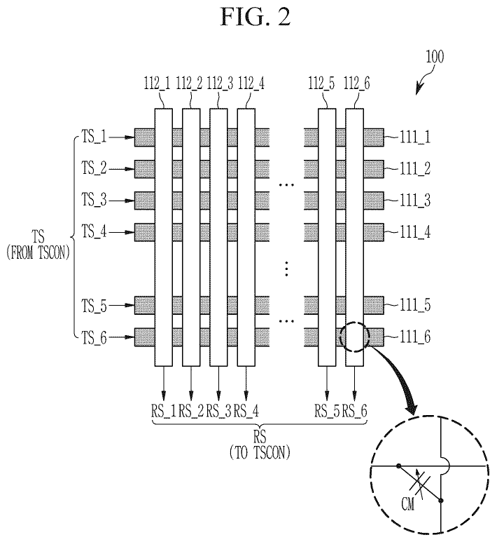

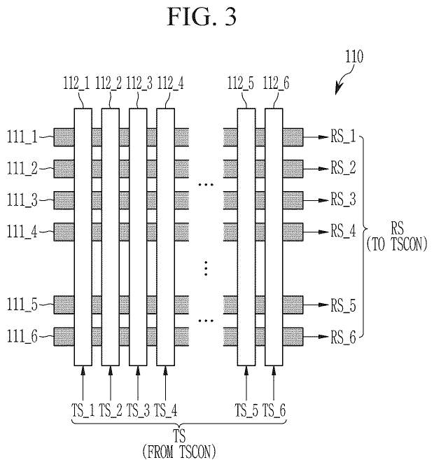

FIGS. 2 and 3 are examples of drawings for explaining a touch sensor according to one or more embodiments. FIGS. 2 and 3 illustrate different examples of operating the touch sensor 110, respectively.

Referring to FIG. 2, the touch sensor 110 according to the embodiment may include a plurality of driving electrodes 111_1 to 111_6 and a plurality of receiving electrodes 112_1 to 112_6. The plurality of driving electrodes 111_1 to 111_6 may include m number of driving electrodes, and the plurality of receiving electrodes 112_1 to 112_6 may include n number of receiving electrodes, wherein m and n may be an integer greater than 1. In some embodiments, m and n may vary depending on the resolution of the touch sensor 110.

The plurality of driving electrodes 111_1 to 111_6 may extend in the first direction, and the plurality of receiving electrodes 112_1 to 112_6 may extend in the second direction intersecting the first direction. In the embodiment, the first direction may be a longitudinal direction and the second direction may be a transverse direction orthogonal to the longitudinal direction; however, the embodiment is not necessarily limited thereto. The plurality of driving electrodes 111_1 to 111_6 and the plurality of receiving electrodes 112_1 to 112_6 may intersect each other, and between the plurality of driving electrodes 111_1 to 111_6 and the plurality of receiving electrodes 112_1 to 112_6 intersecting each other, mutual capacitance CM may be formed.

The plurality of driving electrodes 111_1 to 111_6 may receive driving signals TS. For example, a touch sensor controller TSCON (for example, the touch sensor controller 220 of FIG. 1) may include a plurality of transmitters corresponding to the plurality of driving electrodes 111_1 to 111_6, and the plurality of transmitters may provide driving signals TS to the plurality of driving electrodes 111_1 to 111_6. The driving signals TS may include a plurality of signals TS_1 to TS_6. The plurality of transmitters may apply the plurality of signals TS_1 to TS_6 in a scan manner. In other words, the plurality of signals TS_1 to TS_6 may be applied to the plurality of driving electrodes 111_1 to 111_6 in turn.

In some embodiments, the plurality of driving electrodes 111_1 to 111_6 may operate in a multi-driving manner. The modulated signals TS_1 to TS_6 based on different codes may be applied to the plurality of driving electrodes 111_1 to 111_6 simultaneously. For example, driving signals with opposite polarities may be applied to the first and second driving electrodes 111_1 and 111_2 simultaneously, and then driving signals with opposite polarities may be applied to the third and fourth driving electrodes 111_3 and 111_4 simultaneously.

The plurality of receiving electrodes 112_1 to 112_6 may output sensing signals RS. The sensing signals RS may include a plurality of signals RS_1 to RS_6. For example, the touch sensor controller TSCON may include a plurality of receivers corresponding to the plurality of receiving electrodes 112_1 to 112_6, and the plurality of receivers may receive sensing signals RS from the plurality of receiving electrodes 112_1 to 112_6.

The sensing signals RS may include signals corresponding to the mutual capacitance CM between the plurality of driving electrodes 111_1 to 111_6 and the plurality of receiving electrodes 112_1 to 112_6. For example, when a touch occurs at one sensing node on the touch sensor 110, the mutual capacitance CM of the sensing node may decrease, and level of the sensing signal RS may decrease or increase as compared to before the occurrence of the touch.

The plurality of receivers may output a plurality of touch signals from the plurality of signals RS_1 to RS_6. For example, the plurality of receivers may remove noise signals from the plurality of signals RS_1 to RS_6, and output a plurality of touch signals. The touch sensor controller TSCON may determine the two-dimensional touch coordinates in the first direction and the second direction, on the basis of the plurality of touch signals.

In FIG. 2, it is shown that the plurality of signals TS_1 to TS_6 is applied to the left sides of the plurality of driving electrodes 111_1 to 111_6, and the plurality of signals RS_1 to RS_6 is output from the lower sides of the plurality of receiving electrodes 112_1 to 112_6; however, the embodiment is not necessarily limited thereto. For example, the plurality of signals TS_1 to TS_6 may be applied to the right sides of the plurality of driving electrodes 111_1 to 111_6. The plurality of signals RS_1 to RS_6 may be output from the upper sides of the plurality of receiving electrodes 112_1 to 112_6. As described above, the direction in which the plurality of signals TS_1 to TS_6 is applied and the direction in which the plurality of signals RS_1 to RS_6 is output may be implemented in various ways depending on the routing design of the touch screen device.

In FIG. 3, the plurality of receiving electrodes 112_1 to 112_6 may serve as driving electrodes, and the plurality of driving electrodes 111_1 to 111_6 may serve as receiving electrodes. In other words, the plurality of receiving electrodes 112_1 to 112_6 may receive driving signals TS from the touch sensor controller TSCON. In this case, the touch sensor controller TSCON may apply driving signals TS in a scan manner, a multi-driving manner, or the like.

The plurality of driving electrodes 111_1 to 111_6 may generate sensing signals RS based on the driving signals TS, and output the sensing signals RS to the plurality of receivers. The sensing signals RS may include a plurality of signals RS_1 to RS_6. The plurality of receivers may generate a plurality of touch signals from the sensing signals RS, using a reference signal. The touch sensor controller TSCON may determine the touch coordinates based on the plurality of touch signals.

In FIG. 3, it is shown that the plurality of signals TS_1 to TS_6 is applied to the lower sides of the plurality of receiving electrodes 112_1 to 112_6 and the plurality of signals RS_1 to RS_6 is output from the right sides of the plurality of driving electrodes 111_1 to 111_6; however, the embodiment is not necessarily limited thereto. For example, the plurality of signals TS_1 to TS_6 may be applied to the upper sides of the plurality of receiving electrodes 112_1 to 112_6. The plurality of signals RS_1 to RS_6 may be output from the left sides of the plurality of driving electrodes 111_1 to 111_6. As described above, the direction in which the plurality of signals TS_1 to TS_6 is applied and the direction in which the plurality of signals RS_1 to RS_6 is output may be implemented in various ways depending on the routing design of the touch screen device.

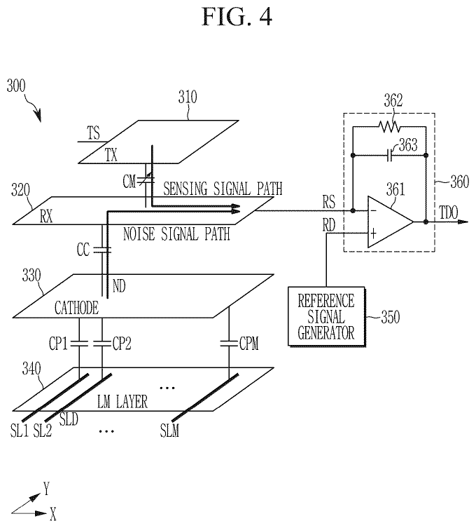

FIG. 4 is a drawing for explaining the operation of a touch screen device according to one or more embodiments.

Referring to FIG. 4, a touch screen device 300 according to one or more embodiments may include a driving electrode (TX) 310, a receiving electrode (RX) 320, a cathode layer (CATHODE) 330, a luminescent layer (LM LAYER) 340, a reference signal generator 350, and a receiver 360. The driving electrode 310 and the receiving electrode 320 may form a touch sensor (the touch sensor 110 of FIG. 1). The description of the plurality of driving electrodes 111_1 to 111_6 and the plurality of receiving electrodes 112_1 to 112_6 of FIG. 2 may be applied equally to the driving electrode 310 and the receiving electrode 320. In FIG. 4, one driving electrode 310 and one receiving electrode 320 are shown for ease of explanation; however, the touch screen device 300 includes a plurality of driving electrodes and a plurality of receiving electrodes.

A touch signal that is generated by a driving signal TS provided from a transmitter may be provided as a sensing signal RS to the receiver 360 through a sensing signal path. The sensing signal path may include mutual capacitance CM between the driving electrode 310 and the receiving electrode 320. The driving signal TS may be provided as a sensing signal RS to the receiver 360 through the mutual capacitance CM. In FIG. 4, only the parasitic capacitance CC between the receiving electrode 320 and the cathode layer 330 is shown; however, the embodiment is not necessarily limited thereto, and it will be appreciated that even between the driving electrode 310 and the cathode layer 330, parasitic capacitance is formed, whereby parasitic capacitance is formed between the touch sensor and the cathode layer 330.

Meanwhile, between the receiving electrode 320 and the cathode layer 330, the parasitic capacitance CC may be formed. A noise signal which is generated as the voltage ND of the cathode layer 330 varies may be introduced into a sensing signal RS through a noise signal path that is formed by the parasitic capacitance CC.

With the trend toward ultra-slim touch displays (for example, the touch display 100 of FIG. 1) for the touch screen device 300, the gap between the touch sensor and the cathode layer 330 is narrowed, and the parasitic capacitance CC increases. Due to the increase in parasitic capacitance CC, noise signals that are introduced into the sensing signal RS increase, making it difficult to distinguish between touch signals and noise signals and making it difficult to distinguish whether a change in the sensing signal RS has been caused by a touch input or a noise signal.

The cathode layer 330 and the luminescent layer 340 may constitute a display panel (the display panel 120 of FIG. 1). The luminescent layer 340 may be formed on the substrate of the display panel, and the cathode layer 330 may be formed on the luminescent layer 340.

The luminescent layer 340 may include a plurality of source lines SL1 to SLM (wherein M is a positive integer). For example, the plurality of source lines SL1 to SLM may be arranged in an X-axis direction and extend in a Y-axis direction. Although not shown in the drawing, the luminescent layer 340 may include a plurality of gate lines, and the plurality of gate lines may be arranged in the Y-axis direction and extend in the X-axis direction. In the luminescent layer 340, a plurality of pixels may be formed at the intersections of the plurality of source lines SL1 to SLM and the plurality of gate lines.

Between the plurality of source lines SL1 to SLM and the cathode layer 330, parasitic capacitance CP1 to CPM may be formed. When a plurality of source signals SLD is applied to the plurality of source lines SL1 to SLM, the voltage ND of the cathode layer 330 may be changed by the parasitic capacitance CP1 to CPM. A constant voltage (for example, a ground voltage) may be applied to the cathode layer 330; however, due to an RC delay caused by the parasitic capacitance CP1 to CPM and the parasitic resistance of the cathode layer 330, the voltage ND of the cathode layer 330 may vary when the plurality of source signals SLD is applied to the plurality of source lines SL1 to SLM.

For example, the plurality of source signals SLD may have rising edges or falling edges, and the voltage ND of the cathode layer 330 may include rising noise or falling noise due to the edges. The voltage ND including such a noise signal may affect the sensing signal RS through the noise signal path of the cathode layer 330 and the receiving electrode 320. In other words, the noise signal may affect the sensing signal RS through the parasitic capacitance CC.

To reduce noise due to changes in the voltage ND of the cathode layer 330, the receiving electrode 320 may extend in a relatively short direction (for example, the X-axis direction) in the touch screen device 300. Accordingly, the driving electrode 310 may extend in a relatively long direction (for example, the Y-axis direction).

The reference signal generator 350 may generate a reference signal RD for removing the noise signal from the sensing signal RS. In one or more embodiments, the reference signal RD may be substantially the same as the noise signal of the sensing signal RS. In one or more embodiments, the reference signal RD may be a direct current (DC) voltage having a predetermined voltage value. The reference signal generator 350 may transmit the reference signal RD to the receiver 360.

The receiver 360 may receive the sensing signal RS and the reference signal RD. The receiver 360 may remove the noise signal from the sensing signal RS on the basis of the reference signal RD. The receiver 360 may generate an output signal TDO by removing the noise signal from the sensing signal RS.

The receiver 360 may include an amplifier 361, a resistor 362, and a capacitor 363. The amplifier 361 may receive the sensing signal RS from the receiving electrode 320 through a first input terminal and receive the reference signal RD from the reference signal generator 350 through a second input terminal. For example, the first input terminal may be an inverting input terminal (−), and the second input terminal may be non-inverting input terminal (+). The amplifier 361 may generate the output signal TDO based on the difference between the sensing signal RS and the reference signal RD. The resistor 362 and the capacitor 363 may form a negative feedback loop between the output terminal and first input terminal of the amplifier 361.

In some embodiments, the receiver 360 may be implemented so as to include the amplifier 361 and the capacitor 363. In some embodiments, the receiver 360 may be implemented so as to include a switch for providing a reset function in place of the resistor 362. In some embodiments, the receiver 360 may be implemented so as to form a unity-gain feedback loop to output current.

The output signal TDO may be used in the touch sensor controller 220 of FIG. 1 to generate touch data. For example, the touch sensor controller 220 may perform conversion (for example, analog-to-digital conversion, current-to-voltage conversion, or the like) on the output signal TDO, or amplify the output signal TDO. Since the output signal TDO does not include the noise signal, the reliability of the touch data of the touch sensor controller 220 can be improved, and the touch sensing sensitivity can be improved. In one or more embodiments, the touch sensor controller 220 may amplify the voltage output signal TDO, filter out out-of-band noise, and perform analog-to-digital conversion. In one or more embodiments, when the receiver 360 outputs current, the touch sensor controller 220 may convert the current output signal into a voltage and amplify it, or may filter out out-of-band noise and perform analog-to-digital conversion.

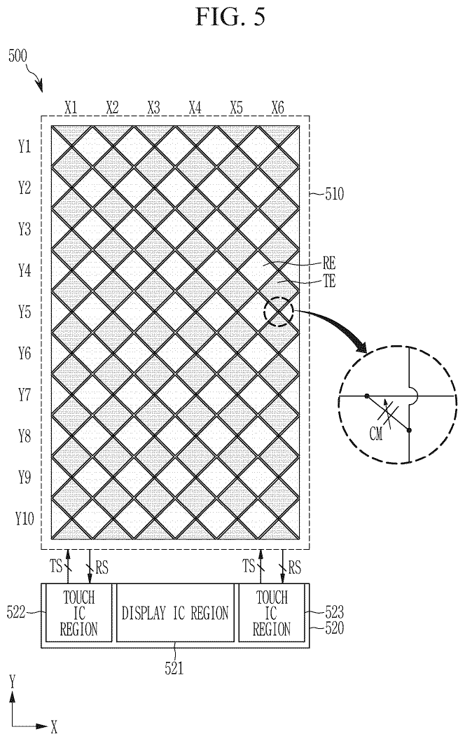

FIG. 5 is a drawing for explaining the operation of a display module according to one or more embodiments.

Referring to FIG. 5, a display module 500 according to one or more embodiments may include a touch screen panel 510 and a touch screen driver circuit 520.

The touch screen panel 510 may include a plurality of touch sensors. For example, the plurality of touch sensors may include a plurality of driving electrodes X1 to X6 and a plurality of receiving electrodes Y1 to Y10. In the embodiment, the number of driving electrodes X1 to X6 which are included in the touch screen panel 510 may be smaller than the number of receiving electrodes Y1 to Y10. In FIG. 5, it is shown that the number of driving electrodes X1 to X6 is 6 and the number of receiving electrodes Y1 to Y10 is 10; however, the embodiment is not necessarily limited thereto, and the numbers of driving electrodes and receiving electrodes which are included in the touch screen panel 510 may be changed according to the resolution of the touch screen panel 510.

In one or more embodiments, the driving electrodes (TE) may be arranged in the X-axis direction and extend in the Y-axis direction. The receiving electrodes (RE) may be arranged in the Y-axis direction and extend in the X-axis direction. The driving electrodes (TE) and the receiving electrodes (RE) may intersect each other, and between the driving electrodes (TE) and the receiving electrodes (RE) intersecting each other, mutual capacitance CM may be formed. In one or more embodiments, the length of the receiving electrodes (RE) may be shorter than that of the driving electrodes (TE).

In some embodiments, the driving electrodes (TE) and/or the receiving electrodes (RE) include a plurality of unit external electrodes connected to each other in a first direction or a second direction (different from the first direction), and the plurality of unit electrodes may have a specific shape (for example, a rhombus shape as shown in FIG. 5) or pattern.

The touch screen driver circuit 520 may include a display driver circuit (for example, the reference symbol “210” in FIG. 1) for driving a display panel, and a touch sensor controller (for example, the reference symbol “220” in FIG. 1) for driving the touch sensors. The display driver circuit may be disposed in a display IC region (DISPLAY IC REGION) 521, and the touch sensor controller may be disposed in touch IC regions (TOUCH IC REGION) 522 and 523.

The display IC region 521 may be positioned in the center of the touch screen driver circuit 520. The display driver circuit that is disposed in the display IC region 521 may include a gamma voltage generator that generates a plurality of gamma voltages, a source driver that generates a plurality of source signals based on the plurality of gamma voltages and applies the plurality of source signals to a plurality of source lines, and the like. In one or more embodiments, the gamma voltage generator may be disposed in the center of the touch screen driver circuit 520.

The touch IC regions 522 and 523 may be positioned at the periphery of the touch screen driver circuit 520, not in the center. For example, the first touch IC region 522 may be positioned on the left side of the display IC region 521, and the second touch IC region 523 may be positioned on the right side of the display IC region 521.

The touch sensor controller that is disposed in the touch IC regions 522 and 523 may generate a plurality of driving signals TS and apply them to the touch screen panel 510. The touch sensor controller may receive a plurality of sensing signals RS from the touch screen panel 510. For example, the touch sensor controller may include transmitters that transmit the plurality of driving signals TS and receivers that receive the plurality of sensing signals RS. In some embodiments, the touch sensor controller may further include converters (for example, analog-to-digital converters (ADCs)) that convert the plurality of sensing signals RS. In some embodiments, the touch sensor controller may further include a processor that generates a plurality of sensing signals RS and processes the plurality of sensing signals RS or converted signals.

The touch IC regions 522 and 523 may include transmission pads and reception pads. The transmission pads may be connected to transmission lines and transfer the plurality of driving signals TS. The reception pads may be connected to reception lines and transfer the plurality of sensing signal RS. For example, the transmission pads may be connected to a plurality of transmitters and the reception pads may be connected to a plurality of receivers.

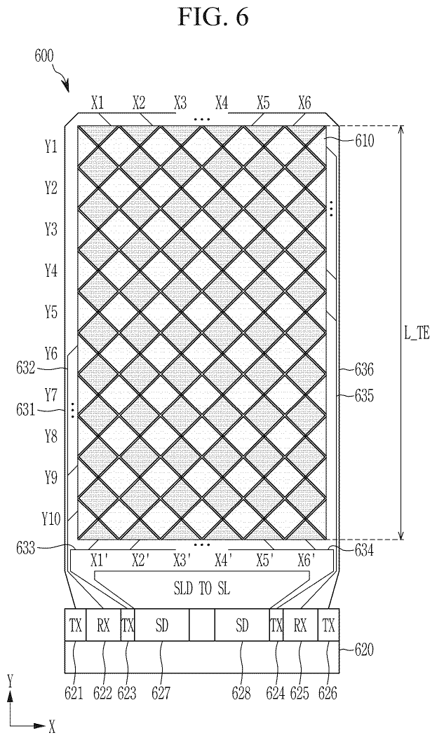

The display module 500 may include a plurality of routing lines that connects the touch screen panel 510 and the touch screen driver circuit 520. Among the plurality of routing lines, lines that are connected to the transmitters or the transmission pads may be referred to as transmission lines, and lines that are connected to the receivers or the reception pads may be referred to as reception lines. In the display module 500, the transmission lines and the reception lines may be disposed so as not to intersect each other. Various embodiments of the transmission lines and the reception lines that connect the touch screen panel 510 and the touch screen driver circuit 520 will be described below with reference to FIGS. 6 to 22.

In other words, the touch IC regions 522 and 523 may include the plurality of transmitters and the plurality of receivers. The plurality of transmitters may correspond to the plurality of driving electrodes X1 to X6, respectively. The transmitters may provide driving signals to the corresponding driving electrodes. The plurality of transmitters may apply the plurality of driving signals TS in turn, or simultaneously.

In one or more embodiments, modulated driving signals TS based on different codes may be simultaneously applied to two or more driving electrodes of the plurality of driving electrodes X1 to X6, which is referred to as multi-driving. For example, driving signals with opposite polarities may be applied to the first and second driving electrodes X1 and X2 simultaneously, and then driving signals with opposite polarities may be applied to the third and fourth driving electrodes X3 and X4 simultaneously.

The plurality of receivers may correspond to the plurality of receiving electrodes Y1 to Y10, respectively. The receivers may receive sensing signals from the receiving electrodes corresponding thereto. In some embodiments, one receiver may be connected to at least two receiving electrode and receive at least two sensing signals.

The sensing signals RS may include touch signals indicating the mutual capacitance CM between the driving electrodes (TE) receiving the driving signals TS and the receiving electrodes (RE) receiving the sensing signals RS. For example, when a touch occurs at one sensing node on the touch screen panel 510, the mutual capacitance CM of the sensing node may be reduced, and the level of the sensing signal RS may be reduced or increased as compared to before the occurrence of the touch.

The receivers may perform conversion (for example, current-to-voltage conversion) on the sensing signals RS or amplify them. The output signals (processed sensing signals) of the receivers may be input to converters (for example, analog-to-digital converters (ADCs).

The ADCs may perform analog-to-digital conversion on the output signals of the plurality of receivers and generate touch data. Accordingly, a plurality of touch values corresponding to the plurality of sensing nodes of the touch screen panel 510 may be generated, and the plurality of touch values may be included in the touch data of one frame.

In some embodiments, driving electrodes 511 may serve as receiving electrodes, and receiving electrodes 512 may serve as driving electrodes.

In some embodiments, the display module 500 may further include a display panel.

Further, in FIG. 5, it is shown that the touch IC regions 522 and 523 include the plurality of transmitters and the plurality of receivers; however, the embodiment is not necessarily limited thereto. In other words, of the touch IC regions 522 and 523, one region (for example, the touch IC region 522) may include the transmitters, and the other region (for example, the touch IC region 523) may include the receivers.

FIG. 6 is a drawing for explaining routing of a display module according to one or more embodiments.

Referring to FIG. 6, a display module 600 according to one or more embodiments may include a touch screen panel 610, a touch screen driver circuit 620, and routing lines 631 to 636. The description of FIGS. 1 to 5 may be equally applied to the touch screen panel 610 and the touch screen driver circuit 620. Accordingly, a redundant description will not be made.

The touch screen panel 610 may include first to p-th driving electrodes to support transmission lines for dual routing. In this case, the first to q-th driving electrodes may be consecutively disposed on the upper side of the touch screen panel 610, and the (q+1) to p-th driving electrodes may be consecutively disposed on the lower side of the touch screen panel 610. Here, q may be an integer greater than 1 and p is an integer greater than q+1. The upper side and lower side of the touch screen panel 610 may be relative positions in the Y-axis direction.

The “upper side” may be the furthest side of the touch screen panel from the touch sensor controller. The “lower side” may be the nearest side of the touch screen panel to the touch sensor controller. A “first side” of the touch screen panel may be adjacent to the “far side,” and a “second side” of the touch screen panel may be opposite the “first side.”

For example, the touch screen panel 610 may include a plurality of driving electrodes X1 to X6 and X1′ to X6′ and a plurality of receiving electrodes Y1 to Y10. The plurality of driving electrodes X1 to X6 may be electrodes disposed consecutively in the X-axis direction on the upper side (i.e. closer to the far side) of the touch screen panel 610. The plurality of driving electrodes X1′ to X6′ may be electrodes disposed consecutively in the X-axis direction on the lower side (i.e. closer to the near side) of the touch screen panel 610.

The plurality of receiving electrodes Y1 to Y10 may be electrodes disposed consecutively in the Y-axis direction of the touch screen panel 610. In some embodiments, the receiving electrodes Y1 to Y5 may be referred to as electrodes disposed on the upper side of the touch screen panel 610, and the receiving electrodes Y6 to Y10 may be referred to as electrodes disposed on the lower side of the touch screen panel 610; however, the embodiments are not necessarily limited thereto.

In some embodiments, the numbers of driving electrodes and receiving electrodes that are included in the touch screen panel 610 may vary depending on the resolution of the touch screen panel 610. In the display module 600, transmission lines may be implemented by dual routing. In other words, the sum of the longitudinal length of the plurality of driving electrodes X1 to X6 and the longitudinal length of the plurality of driving electrodes X1′ to X6′ may be the longitudinal length (L_TE) of the touch screen panel 610. In some embodiments, the longitudinal length of the plurality of driving electrodes X1 to X6 and X1′ to X6′ may be half the longitudinal length (L_TE) of the touch screen panel 610; however, the embodiments are not necessarily limited thereto. In some embodiments, the plurality of driving electrodes X1 to X6 and X1′ to X6′ may serve as receiving electrodes, and the plurality of receiving electrodes Y1 to Y10 may serve as driving electrodes.

The touch screen driver circuit 620 may include a display driver circuit and a touch sensor controller. The display driver circuit may be disposed in the center (or middle) of the touch screen driver circuit 620. In some embodiments, the center of the touch screen driver circuit 620 may not necessarily refer to the exact center. The touch sensor controller may be disposed on the periphery of the display driver circuit.

In one or more embodiments, the display driver circuit may include source drivers (SD) 627 and 628. The source drivers 627 and 628 may generate a plurality of source signals SLD based on a plurality of gamma voltages and an input image signal. The source drivers 627 and 628 may transmit the plurality of source signals SLD to a plurality of source lines SL. Pixels of the display panel connected to the plurality of source lines SL may display an image based on the plurality of source signals SLD.

In one or more embodiments, the display driver circuit may further include at least one of a gamma voltage generator and a memory. The gamma voltage generator may generate a plurality of gamma voltages and transmits them to the source drivers 627 and 628. In some embodiments, the gamma voltage generator may be disposed between the source drivers 627 and 628.

The memory may store input image signals received from a host. For example, the memory may store input image signals in units of a plurality of lines, or store an input image signal of one frame. The memory may provide input image signals to the source drivers 627 and 628 on a line-by-line basis. In some embodiments, the memory may be implemented as a static random access memory (SRAM).

In some embodiments, the display driver circuit may further include gate drivers and the like which are components necessary to display images.

In one or more embodiments, the touch sensor controller may include transmitters 621, 623, 624, and 626 and receivers 622 and 625. The touch sensor controller may further include a processor for driving the transmitters 621, 623, 624, and 626 and processing sensing signals received from the receivers 622 and 625, analog-to-digital converters (ADCs) for performing conversion (for example, analog-to-digital conversion) on sensing signals, which are not shown in FIG. 6 for ease of explanation. For example, the regions where the transmitters 621 and 626 are disposed may include processors for generating driving signals. In some embodiments, the regions where the transmitters 623 and 624 are disposed may include processors for generating driving signals. The regions where the receivers 622 and 625 are disposed may include analog-to-digital converters (ADCs).

In one or more embodiments, the touch sensor controller may be disposed symmetrically. The touch sensor controller may be symmetrically disposed on the left side and right side of the display driver circuit. For example, the transmitter 623, the receiver 622, and the transmitter 621 may be sequentially disposed in the left direction (i.e. a “first side”) of the display driver circuit (i.e., the left direction of the source driver 627 in FIG. 6), and the transmitter 624, the receiver 625, and the transmitter 626 may be sequentially disposed in the right direction (i.e. a “second side” opposite the “first side”; the right direction of the source driver 628).

The touch screen panel 610 and the touch screen driver circuit 620 may be connected through the routing lines 631 to 636. The routing lines 631, 633, 634, and 636 may be transmission lines, and the routing lines 632 and 635 may be reception lines. In some embodiments, the transmission lines may be implemented by single routing or may be implemented by dual routing. The reception lines may be implemented by single routing. In some embodiments, the receivers that are connected to the reception lines may be disposed on one side or both sides of the display driver circuit.

In FIG. 6, the transmission lines may be implemented by dual routing, and the receivers 622 and 625 may be disposed on both sides of the display driver circuit. The routing lines 631, 633, 634, and 636 may be connected to the plurality of driving electrodes X1 to X6 and X1′ to X6′. For example, the routing line 631 may be connected to the driving electrodes X1 to X3, the routing line 633 may be connected to the driving electrodes X1′ to X3′, the routing line 634 may be connected to the driving electrodes X4′ to X6′, and the routing line 636 may be connected to the driving electrodes X4 to X6,

However, the embodiment is not necessarily limited thereto, and the number of driving electrodes that are connected to each of the routing lines 631, 633, 634, and 636 may be changed. Further, the routing lines 631 and 636 may be connected to the upper sides of the plurality of driving electrodes X1 to X6, and the routing lines 633 and 634 may be connected to the lower sides of the plurality of driving electrodes X1′ to X6′.

The routing lines 632 and 635 may be connected to the plurality of receiving electrodes Y1 to Y10. For example, the routing line 632 may be connected to the receiving electrodes Y6 to Y10, and the routing line 635 may be connected to the receiving electrodes Y1 to Y5. In other embodiments, the routing lines 632 and 635 may be connected to the plurality of receiving electrodes Y1 to Y10 in a zigzag manner. For example, the routing line 632 may be connected to the even-numbered receiving electrodes Y2, Y4, Y6, Y8, and Y10 (or the odd-numbered receiving electrodes), and the routing line 635 may be configured to the odd-numbered receiving electrodes Y1, Y3, Y5, Y7, and Y9 (or the even-numbered receiving electrodes). However, the embodiments are not necessarily limited thereto, and the number of receiving electrodes that are connected to each of the routing lines 632 and 635 may be changed. Further, the routing line 632 may be connected to the left sides of the receiving electrodes Y6 to Y10, and the routing line 635 may be connected to the right sides of the receiving electrodes Y1 to Y5.

The transmitters 621, 623, 624, and 626 and the receivers 622 and 625 may be connected to the electrodes X1 to X6, X1′ to X6′, and Y1 to Y10 through the routing lines 631 to 636. For example, the transmitter 621 may be connected to the routing line 631, the receiver 622 may be connected to the routing line 632, the transmitter 623 may be connected to the routing line 633, the transmitter 624 may be connected to the routing line 634, the receiver 625 may be connected to the routing line 635, and the transmitter 626 may be connected to the routing line 636. In other words, the transmitters 621, 623, 624, and 626 may transmit driving signals to the plurality of driving electrodes X1 to X6 and X1′ to X6′ through the routing lines 631, 633, 634, and 636. The receivers 622 and 625 may receive sensing signals from the plurality of receiving electrodes Y1 to Y10 through the routing lines 632 and 635.

In the display module 600 according to the embodiment, the transmitter and receiver sets may be symmetrically disposed on both sides of the display driver circuit to improve the wiring connectivity of the touch screen panel 610 and lower the die height of the touch screen driver circuit 620. Accordingly, the number of dies for the touch screen driver circuit 620 that can be obtained from one wafer can increase.

Further, the display module 600 may include the transmission lines for dual routing, resulting in a decrease in the resistance of the wiring. Accordingly, the time constant can decrease and the settling time can shorten. In the display module 600, the receivers 622 and 625 may be disposed on both sides of the display driver circuit. Accordingly, it is possible to reduce the deviation between channels of an analog front end (AFE).

In some embodiments, the display module 600 may further include shielding members between the transmitters 621, 623, 624, and 626 and the receivers 622 and 625 or between the transmission lines and the reception lines. The shielding members are members for preventing electromagnetic interference, and may include shielding lines, shielding layers, and the like.

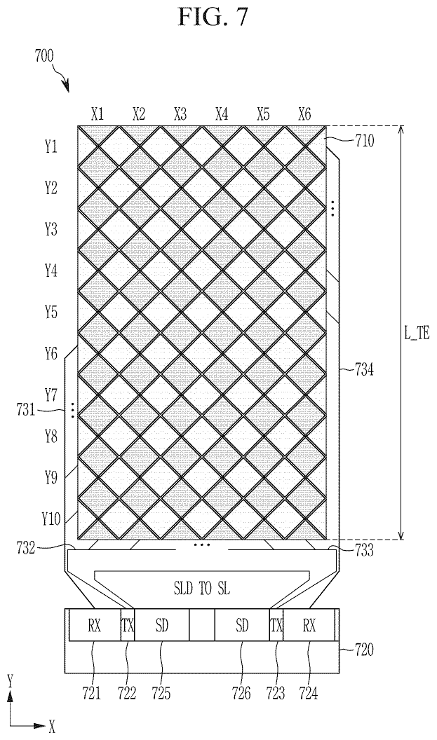

FIG. 7 is a drawing for explaining routing of a display module according to one or more embodiments.

Referring to FIG. 7, a display module 700 according to one or more embodiments may include a touch screen panel 710, a touch screen driver circuit 720, and routing lines 731 to 734. The display module 700 may be the same as the display module 600 of FIG. 6 except that it includes transmission lines for single routing in place of the transmission lines for dual routing. The description of FIGS. 1 to 5 may be equally applied to the touch screen panel 710 and the touch screen driver circuit 720. Accordingly, a redundant description will not be made.

The touch screen panel 710 may include first to r-th driving electrodes which are consecutively disposed in the touch screen panel 710 to support the transmission lines for single routing. Here, r may be an integer greater than 1.

For example, the touch screen panel 710 may include a plurality of driving electrodes X1 to X6 and a plurality of receiving electrodes Y1 to Y10. In some embodiments, the numbers of driving electrodes and receiving electrodes that are included in the touch screen panel 710 may vary depending on the resolution of the touch screen panel 710. In the display module 700, transmission lines may be implemented by single routing. In other words, the longitudinal length of the plurality of driving electrodes X1 to X6 may be the longitudinal length (L_TE) of the touch screen panel 710. In some embodiments, the plurality of driving electrodes X1 to X6 may serve as receiving electrodes, and the plurality of receiving electrodes Y1 to Y10 may serve as driving electrodes.

The touch screen driver circuit 720 may include a display driver circuit and a touch sensor controller. The display driver circuit may be disposed in the center (or middle) of the touch screen driver circuit 720. In some embodiments, the center of the touch screen driver circuit 720 may not necessarily refer to the exact center. The touch sensor controller may be disposed on the periphery of the display driver circuit.

In one or more embodiments, the display driver circuit may include source drivers (SD) 725 and 726. The description of FIG. 6 may be equally applied to the configurations and operations of the display driver circuit and the source drivers 725 and 726. The source drivers 725 and 726 may generate a plurality of source signals SLD and transmit them to a plurality of source lines SL. Pixels of the display panel connected to the plurality of source lines SL may display an image based on the plurality of source signals SLD.

In one or more embodiments, the touch sensor controller may include transmitters 722 and 723 and receivers 721 and 724. The touch sensor controller may further include a processor for driving the transmitters 722 and 723 and processing sensing signals received from the receivers 721 and 724, analog-to-digital converters (ADCs) for performing conversion (for example, analog-to-digital conversion) on sensing signals, which are not shown in FIG. 7 for ease of explanation. For example, the regions where the transmitters 722 and 723 are disposed may include processors for generating driving signals. The regions where the receivers 721 and 724 are disposed may include analog-to-digital converters (ADCs).

In one or more embodiments, the touch sensor controller may be disposed symmetrically. The touch sensor controller may be symmetrically disposed on the left side and right side of the display driver circuit. For example, the transmitter 722 and the receiver 721 may be sequentially disposed in the left direction of the display driver circuit (i.e., the left direction of the source driver 725 in FIG. 7), and the transmitter 723 and the receiver 724 may be sequentially disposed in the right direction (i.e. the right direction of the source driver 726). In other words, these components may be aligned with the driver circuit in the second direction.

The touch screen panel 710 and the touch screen driver circuit 720 may be connected through the routing lines 731 to 734. The routing lines 732 and 733 may be transmission lines, and the routing lines 731 and 734 may be reception lines. In some embodiments, the transmission lines may be implemented by single routing or may be implemented by dual routing. The reception lines may be implemented by single routing. In some embodiments, the receivers that are connected to the reception lines may be disposed on one side or both sides of the display driver circuit.

In FIG. 7, the transmission lines may be implemented by single routing, and the receivers 721 and 724 may be disposed on both sides of the display driver circuit. The routing lines 732 and 733 may be connected to the plurality of driving electrodes X1 to X6. Further, the routing lines 732 and 733 may be connected to the lower sides of the plurality of driving electrodes X1 to X6.

The routing lines 731 and 734 may be connected to the plurality of receiving electrodes Y1 to Y10. For example, the routing line 731 may be connected to the receiving electrodes Y6 to Y10, and the routing line 734 may be connected to the receiving electrodes Y1 to Y5. However, the embodiments are not necessarily limited thereto, and the number of receiving electrodes that are connected to each of the routing lines 731 and 734 may be changed. Further, the routing line 731 may be connected to the left sides of the receiving electrodes Y6 to Y10, and the routing line 734 may be connected to the right sides of the receiving electrodes Y1 to Y5.

The transmitters 722 and 723 and the receivers 721 and 724 may be connected to the electrodes X1 to X6 and Y1 to Y10 through the routing lines 731 to 734. For example, the receiver 721 may be connected to the routing line 731, the transmitter 722 may be connected to the routing line 732, the transmitter 723 may be connected to the routing line 733, and the receiver 724 may be connected to the routing line 734. In other words, the transmitters 722 and 723 may transmit driving signals to the plurality of driving electrodes X1 to X6 through the routing lines 732 and 733. The receivers 721 and 724 may receive sensing signals from the plurality of receiving electrodes Y1 to Y10 through the routing lines 731 and 734.

In the display module 700 according to the embodiment, the transmitter and receiver sets may be symmetrically disposed on both sides of the display driver circuit to improve the wiring connectivity of the touch screen panel 710 and lower the die height of the touch screen driver circuit 720. Accordingly, the number of dies for the touch screen driver circuit 720 that can be obtained from one wafer can increase.

Further, in the display module 700, the receivers 721 and 724 may be disposed on both sides of the display driver circuit. Accordingly, it is possible to reduce the deviation between channels of an analog front end (AFE).

In some embodiments, the display module 700 may further include shielding members between the transmitters 722 and 723 and the receivers 721 and 724 or between the transmission lines and the reception lines. The shielding members are members for preventing electromagnetic interference, and may include shielding lines, shielding layers, and the like.

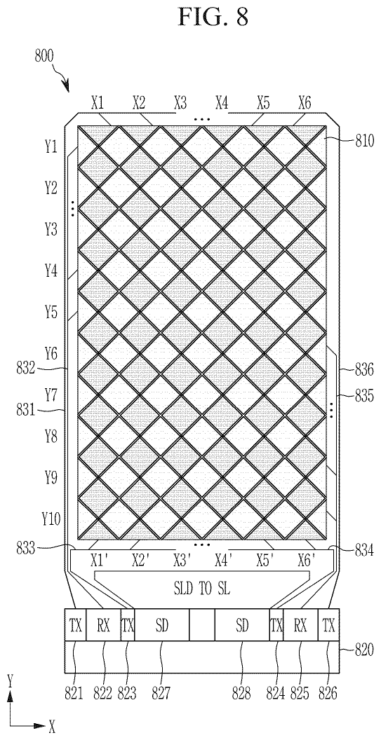

FIG. 8 is a drawing for explaining routing of a display module according to one or more embodiments.

Referring to FIG. 8, a display module 800 according to one or more embodiments may include a touch screen panel 810, a touch screen driver circuit 820, and routing lines 831 to 836. The display module 800 may differ from the display module 600 of FIG. 6 only in receiving electrodes to which reception lines are connected. The description of FIGS. 1 to 5 may be equally applied to the touch screen panel 810 and the touch screen driver circuit 820. Accordingly, a redundant description will not be made.

The touch screen panel 810 may include a plurality of driving electrodes X1 to X6 and X1′ to X6′ and a plurality of receiving electrodes Y1 to Y10. In some embodiments, the numbers of driving electrodes and receiving electrodes that are included in the touch screen panel 810 may vary depending on the resolution of the touch screen panel 810. In the display module 800, transmission lines may be implemented by dual routing. In some embodiments, the plurality of driving electrodes X1 to X6 and X1′ to X6′ may serve as receiving electrodes, and the plurality of receiving electrodes Y1 to Y10 may serve as driving electrodes.

The touch screen driver circuit 820 may include a display driver circuit and a touch sensor controller. The display driver circuit may be disposed in the center (or middle) of the touch screen driver circuit 820. In some embodiments, the center of the touch screen driver circuit 820 may not necessarily refer to the exact center. The touch sensor controller may be disposed on the periphery of the display driver circuit.

In one or more embodiments, the display driver circuit may include source drivers (SD) 827 and 828. The description of FIG. 6 may be equally applied to the configurations and operations of the display driver circuit and the source drivers 827 and 828. The source drivers 827 and 828 may generate a plurality of source signals SLD and transmit them to a plurality of source lines SL. Pixels of the display panel connected to the plurality of source lines SL may display an image based on the plurality of source signals SLD.

In one or more embodiments, the touch sensor controller may include transmitters 821, 823, 824, and 826 and receivers 822 and 825. The touch sensor controller may further include a processor for driving the transmitters 821, 823, 824, and 826 and processing sensing signals received from the receivers 822 and 825, analog-to-digital converters (ADCs) for performing conversion (for example, analog-to-digital conversion) on sensing signals, which are not shown in FIG. 8 for ease of explanation. For example, the regions where the transmitters 821 and 826 are disposed may include processors for generating driving signals. In some embodiments, the regions where the transmitters 823 and 824 are disposed may include processors for generating driving signals. The regions where the receivers 822 and 825 are disposed may include analog-to-digital converters (ADCs).

In one or more embodiments, the touch sensor controller may be disposed symmetrically. The touch sensor controller may be symmetrically disposed on the left side and right side of the display driver circuit. For example, the transmitter 823, the receiver 822, and the transmitter 821 may be sequentially disposed in the left direction of the display driver circuit (i.e., the left direction of the source driver 827 in FIG. 8), and the transmitter 824, the receiver 825, and the transmitter 826 may be sequentially disposed in the right direction (i.e., the right direction of the source driver 828).

The touch screen panel 810 and the touch screen driver circuit 820 may be connected through the routing lines 831 to 836. The routing lines 831, 833, 834, and 836 may be transmission lines, and the routing lines 832 and 835 may be reception lines. In some embodiments, the transmission lines may be implemented by single routing or may be implemented by dual routing. The reception lines may be implemented by single routing. In some embodiments, the receivers that are connected to the reception lines may be disposed on one side or both sides of the display driver circuit.

In FIG. 8, the transmission lines may be implemented by dual routing, and the receivers 822 and 825 may be disposed on both sides of the display driver circuit. The routing lines 831, 833, 834, and 836 may be connected to the plurality of driving electrodes X1 to X6 and X1′ to X6′. For example, the routing line 831 may be connected to the driving electrodes X1 to X3, the routing line 833 may be connected to the driving electrodes X1′ to X3′, the routing line 834 may be connected to the driving electrodes X4′ to X6′, and the routing line 836 may be connected to the driving electrodes X4 to X6. However, the embodiment is not necessarily limited thereto, and the number of driving electrodes that are connected to each of the routing lines 831, 833, 834, and 836 may be changed. Further, the routing lines 831 and 836 may be connected to the upper sides of the plurality of driving electrodes X1 to X6, and the routing lines 833 and 834 may be connected to the lower sides of the plurality of driving electrodes X1′ to X6′.

The routing lines 832 and 835 may be connected to the plurality of receiving electrodes Y1 to Y10. For example, the routing line 832 may be connected to the receiving electrodes Y1 to Y5, and the routing line 835 may be connected to the receiving electrodes Y6 to Y10. However, the embodiments are not necessarily limited thereto, and the number of receiving electrodes that are connected to each of the routing lines 832 and 835 may be changed. Further, the routing line 832 may be connected to the left sides of the receiving electrodes Y1 to Y5, and the routing line 835 may be connected to the right sides of the receiving electrodes Y6 to Y10.

The transmitters 821, 823, 824, and 826 and the receivers 822 and 825 may be connected to the electrodes X1 to X6, X1′ to X6′, and Y1 to Y10 through the routing lines 831 to 836. For example, the transmitter 821 may be connected to the routing line 831, the receiver 822 may be connected to the routing line 832, the transmitter 823 may be connected to the routing line 833, the transmitter 824 may be connected to the routing line 834, the receiver 825 may be connected to the routing line 835, and the transmitter 826 may be connected to the routing line 836. In other words, the transmitters 821, 823, 824, and 826 may transmit driving signals to the plurality of driving electrodes X1 to X6 and X1′ to X6′ through the routing lines 831, 833, 834, and 836. The receivers 822 and 825 may receive sensing signals from the plurality of receiving electrodes Y1 to Y10 through the routing lines 832 and 835.

In the display module 800 according to the embodiment, the transmitter and receiver sets may be symmetrically disposed on both sides of the display driver circuit to improve the wiring connectivity of the touch screen panel 810 and lower the die height of the touch screen driver circuit 820. Accordingly, the number of dies for the touch screen driver circuit 820 that can be obtained from one wafer can increase.

Further, the display module 800 may include the transmission lines for dual routing, resulting in a decrease in the resistance of the wiring. Accordingly, the time constant can decrease and the settling time can shorten. In the display module 800, the receivers 822 and 825 may be disposed on both sides of the display driver circuit. Accordingly, it is possible to reduce the deviation between channels of an analog front end (AFE).

In some embodiments, the display module 800 may further include shielding members between the transmitters 821, 823, 824, and 826 and the receivers 822 and 825 or between the transmission lines and the reception lines. The shielding members are members for preventing electromagnetic interference, and may include shielding lines, shielding layers, and the like.

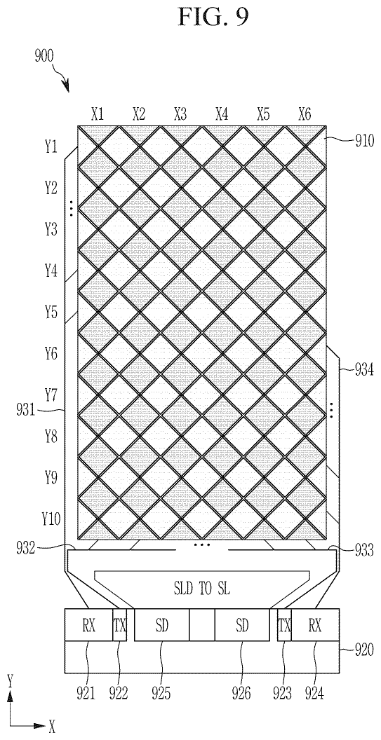

FIG. 9 is a drawing for explaining routing of a display module according to one or more embodiments.

Referring to FIG. 9, a display module 900 according to one or more embodiments may include a touch screen panel 910, a touch screen driver circuit 920, and routing lines 931 to 934. The display module 900 may differ from the display module 700 of FIG. 7 only in receiving electrodes to which reception lines are connected. The description of FIGS. 1 to 5 may be equally applied to the touch screen panel 910 and the touch screen driver circuit 920. Accordingly, a redundant description will not be made.

The touch screen panel 910 may include a plurality of driving electrodes X1 to X6 and a plurality of receiving electrodes Y1 to Y10. In some embodiments, the numbers of driving electrodes and receiving electrodes that are included in the touch screen panel 910 may vary depending on the resolution of the touch screen panel 910. In the display module 900, transmission lines may be implemented by single routing. In some embodiments, the plurality of driving electrodes X1 to X6 may serve as receiving electrodes, and the plurality of receiving electrodes Y1 to Y10 may serve as driving electrodes.

The touch screen driver circuit 920 may include a display driver circuit (including, for example, source drivers 925 and 926) and a touch sensor controller (including, for example, transmitters 922 and 923 and receivers 921 and 924). The display driver circuit may be disposed in the center (or middle) of the touch screen driver circuit 920. In some embodiments, the center of the touch screen driver circuit 920 may not necessarily refer to the exact center. The touch sensor controller may be disposed on the periphery of the display driver circuit.

In one or more embodiments, the touch sensor controller may be disposed symmetrically. The touch sensor controller may be symmetrically disposed on the left side and right side of the display driver circuit. For example, the transmitter 922 and the receiver 921 may be sequentially disposed in the left direction of the display driver circuit (i.e., the left direction of the source driver 925 in FIG. 9), and the transmitter 923 and the receiver 924 may be sequentially disposed in the right direction (i.e. the right direction of the source driver 926).

The touch screen panel 910 and the touch screen driver circuit 920 may be connected through the routing lines 931 to 934. The routing lines 932 and 933 may be transmission lines, and the routing lines 931 and 934 may be reception lines. In some embodiments, the transmission lines may be implemented by single routing or may be implemented by dual routing. The reception lines may be implemented by single routing. In some embodiments, the receivers that are connected to the reception lines may be disposed on one side or both sides of the display driver circuit.

In FIG. 9, the transmission lines may be implemented by single routing, and the receivers 921 and 924 may be disposed on both sides of the display driver circuit. The routing lines 932 and 933 may be connected to the plurality of driving electrodes X1 to X6. Further, the routing lines 932 and 933 may be connected to the lower sides of the plurality of driving electrodes X1 to X6.

The routing lines 931 and 934 may be connected to the plurality of receiving electrodes Y1 to Y10. For example, the routing line 931 may be connected to the receiving electrodes Y1 to Y5, and the routing line 934 may be connected to the receiving electrodes Y6 to Y10. However, the embodiments are not necessarily limited thereto, and the number of receiving electrodes that are connected to each of the routing lines 931 and 934 may be changed. Further, the routing line 931 may be connected to the left sides of the receiving electrodes Y1 to Y5, and the routing line 934 may be connected to the right sides of the receiving electrodes Y6 to Y10.

The transmitters 922 and 923 and the receivers 921 and 924 may be connected to the electrodes X1 to X6 and Y1 to Y10 through the routing lines 931 to 934. For example, the receiver 921 may be connected to the routing line 931, the transmitter 922 may be connected to the routing line 932, the transmitter 923 may be connected to the routing line 933, and the receiver 924 may be connected to the routing line 934. In other words, the transmitters 922 and 923 may transmit driving signals to the plurality of driving electrodes X1 to X6 through the routing lines 932 and 933. The receivers 921 and 924 may receive sensing signals from the plurality of receiving electrodes Y1 to Y10 through the routing lines 931 and 934.

In the display module 900 according to the embodiment, the transmitter and receiver sets may be symmetrically disposed on both sides of the display driver circuit to improve the wiring connectivity of the touch screen panel 910 and lower the die height of the touch screen driver circuit 920. Accordingly, the number of dies for the touch screen driver circuit 920 that can be obtained from one wafer can increase.

Further, in the display module 900, the receivers 921 and 924 may be disposed on both sides of the display driver circuit. Accordingly, it is possible to reduce the deviation between channels of an analog front end (AFE).

In some embodiments, the display module 900 may further include shielding members between the transmitters 922 and 923 and the receivers 921 and 924 or between the transmission lines and the reception lines. The shielding members are members for preventing electromagnetic interference, and may include shielding lines, shielding layers, and the like.

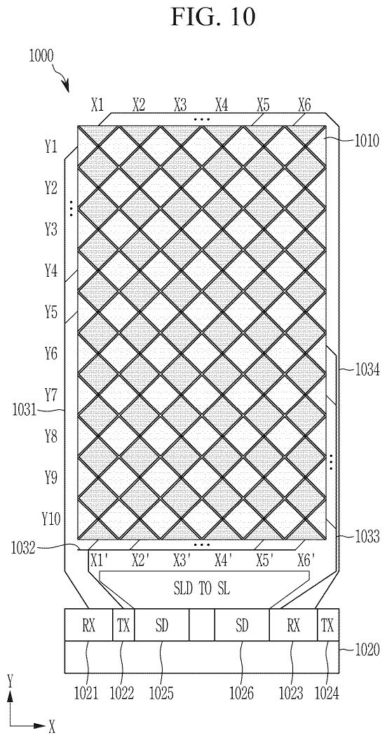

FIG. 10 is a drawing for explaining routing of a display module according to one or more embodiments.

Referring to FIG. 10, a display module 1000 according to one or more embodiments may include a touch screen panel 1010, a touch screen driver circuit 1020, and routing lines 1031 to 1034. The description of FIGS. 1 to 5 may be equally applied to the touch screen panel 1010 and the touch screen driver circuit 1020. Accordingly, a redundant description will not be made.

The touch screen panel 1010 may include a plurality of driving electrodes X1 to X6 and X1′ to X6′ and a plurality of receiving electrodes Y1 to Y10. In some embodiments, the numbers of driving electrodes and receiving electrodes that are included in the touch screen panel 1010 may vary depending on the resolution of the touch screen panel 1010. In the display module 1000, transmission lines may be implemented by single routing. In some embodiments, the plurality of driving electrodes X1 to X6 and X1′ to X6′ may serve as receiving electrodes, and the plurality of receiving electrodes Y1 to Y10 may serve as driving electrodes.

The touch screen driver circuit 1020 may include a display driver circuit (including, for example, source drivers 1025 and 1026) and a touch sensor controller (including, for example, transmitters 1022 and 1024 and receivers 1021 and 1023). The display driver circuit may be disposed in the center (or middle) of the touch screen driver circuit 1020. In some embodiments, the center of the touch screen driver circuit 1020 may not necessarily refer to the exact center.

The touch sensor controller may be disposed on the periphery of the display driver circuit. For example, the receiver 1021 and the transmitter 1022 may be disposed on the left side of the display driver circuit (i.e., the left side of the source driver 1025 in FIG. 10), and the receiver 1023 and the transmitter 1024 may be disposed on the right side (i.e., the right side of the source driver 1026).

The touch screen panel 1010 and the touch screen driver circuit 1020 may be connected through the routing lines 1031 to 1034. The routing lines 1032 and 1034 may be transmission lines, and the routing lines 1031 and 1033 may be reception lines. In some embodiments, the transmission lines may be implemented by single routing or may be implemented by dual routing. The reception lines may be implemented by single routing. In some embodiments, the receivers that are connected to the reception lines may be disposed on one side or both sides of the display driver circuit.

In FIG. 10, the transmission lines may be implemented by dual routing, and the transmitters 1022 and 1024 and the receivers 1021 and 1023 may be disposed on both sides of the display driver circuit. The routing lines 1032 and 1034 may be connected to the plurality of driving electrodes X1 to X6 and X1′ to X6′. For example, the routing line 1032 may be connected to the lower sides of the driving electrodes X1′ to X6′, and the routing line 1034 may be connected to the upper sides of the driving electrodes X1 to X6.

The routing lines 1031 and 1033 may be connected to the plurality of receiving electrodes Y1 to Y10. For example, the routing line 1031 may be connected to the receiving electrodes Y1 to Y5, and the routing line 1033 may be connected to the receiving electrodes Y6 to Y10. However, the embodiments are not necessarily limited thereto, and the number of receiving electrodes that are connected to each of the routing lines 1031 and 1033 may be changed. Further, the routing line 1031 may be connected to the left sides of the receiving electrodes Y1 to Y5, and the routing line 1033 may be connected to the right sides of the receiving electrodes Y6 to Y10.

The transmitters 1022 and 1024 and the receivers 1021 and 1023 may be connected to the electrodes X1 to X6, X1′ to X6′, and Y1 to Y10 through the routing lines 1031 to 1034. For example, the receiver 1021 may be connected to the routing line 1031, the transmitter 1022 may be connected to the routing line 1032, the receiver 1023 may be connected to the routing line 1033, and the transmitter 1024 may be connected to the routing line 1034. In other words, the transmitters 1022 and 1024 may transmit driving signals to the plurality of driving electrodes X1 to X6 and X1′ to X6′ through the routing lines 1032 and 1034. The receivers 1021 and 1023 may receive sensing signals from the plurality of receiving electrodes Y1 to Y10 through the routing lines 1031 and 1033.

In the display module 1000 according to the embodiment, the transmitter and receiver sets may be disposed on both sides of the display driver circuit to improve the wiring connectivity of the touch screen panel 1010 and lower the die height of the touch screen driver circuit 1020. Accordingly, the number of dies for the touch screen driver circuit 1020 that can be obtained from one wafer can increase.

The display module 1000 may include the transmission lines for dual routing, resulting in a decrease in the resistance of the wiring. Accordingly, the time constant can decrease and the settling time can shorten. Further, in the display module 1000, the receivers 1021 and 1023 may be disposed on both sides of the display driver circuit. Accordingly, it is possible to reduce the deviation between channels of an analog front end (AFE).

In some embodiments, the display module 1000 may further include shielding members between the transmitters 1022 and 1024 and the receivers 1021 and 1023 or between the transmission lines and the reception lines. The shielding members are members for preventing electromagnetic interference, and may include shielding lines, shielding layers, and the like.

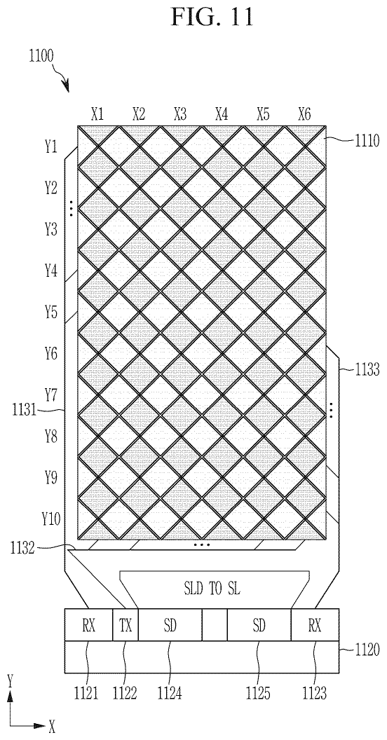

FIG. 11 is a drawing for explaining routing of a display module according to one or more embodiments.

Referring to FIG. 11, a display module 1100 according to one or more embodiments may include a touch screen panel 1110, a touch screen driver circuit 1120, and routing lines 1131 to 1133. The display module 1100 may be the same as the display module 1000 of FIG. 10 except that it includes transmission lines for single routing in place of the transmission lines for dual routing. The description of FIGS. 1 to 5 may be equally applied to the touch screen panel 1110 and the touch screen driver circuit 1120. Accordingly, a redundant description will not be made.

The touch screen panel 1110 may include a plurality of driving electrodes X1 to X6 and a plurality of receiving electrodes Y1 to Y10. In some embodiments, the numbers of driving electrodes and receiving electrodes that are included in the touch screen panel 1110 may vary depending on the resolution of the touch screen panel 1110. In the display module 1100, transmission lines may be implemented by single routing. In some embodiments, the plurality of driving electrodes X1 to X6 may serve as receiving electrodes, and the plurality of receiving electrodes Y1 to Y10 may serve as driving electrodes.

The touch screen driver circuit 1120 may include a display driver circuit (including, for example, source drivers 1124 and 1125) and a touch sensor controller (including, for example, a transmitter 1122 and receivers 1121 and 1123). The display driver circuit may be disposed in the center (or middle) of the touch screen driver circuit 1120. In some embodiments, the center of the touch screen driver circuit 1120 may not necessarily refer to the exact center.

The touch sensor controller may be disposed on the periphery of the display driver circuit. For example, the receiver 1121 and the transmitter 1122 may be disposed on the left side of the display driver circuit, and the receiver 1123 may be disposed on the right side.

The touch screen panel 1110 and the touch screen driver circuit 1120 may be connected through the routing lines 1131 to 1133. The routing line 1132 may be a transmission line, and the routing lines 1131 and 1133 may be reception lines. In some embodiments, the transmission lines may be implemented by single routing or may be implemented by dual routing. The reception lines may be implemented by single routing. In some embodiments, the receivers that are connected to the reception lines may be disposed on one side or both sides of the display driver circuit.

In FIG. 11, the transmission lines may be implemented by single routing, and the receivers 1121 and 1123 may be disposed on both sides of the display driver circuit. The transmitter 1122 may be disposed on the left side of the display driver circuit. The routing line 1132 may be connected to the plurality of driving electrodes X1 to X6. For example, the routing line 1132 may be connected to the lower sides of the driving electrodes X1 to X6. In some embodiments, the routing line 1132 may be connected to the upper sides of the driving electrodes X1 to X6. In this case, the transmitter 1122 may be disposed on the left side of the receiver 1121 or the right side of the receiver 1123.

The routing lines 1131 and 1133 may be connected to the plurality of receiving electrodes Y1 to Y10. For example, the routing line 1131 may be connected to the receiving electrodes Y1 to Y5, and the routing line 1133 may be connected to the receiving electrodes Y6 to Y10. However, the embodiments are not necessarily limited thereto, and the number of receiving electrodes that are connected to each of the routing lines 1131 and 1133 may be changed. Further, the routing line 1131 may be connected to the left sides of the receiving electrodes Y1 to Y5, and the routing line 1133 may be connected to the right sides of the receiving electrodes Y6 to Y10.

The transmitter 1122 and the receivers 1121 and 1123 may be connected to the electrodes X1 to X6 and Y1 to Y10 through the routing lines 1131 to 1133. For example, the receiver 1121 may be connected to the routing line 1131, the transmitter 1122 may be connected to the routing line 1132, and the receiver 1123 may be connected to the routing line 1133. In other words, the transmitter 1122 may transmit driving signals to the plurality of driving electrodes X1 to X6 through the routing line 1132. The receivers 1121 and 1123 may receive sensing signals from the plurality of receiving electrodes Y1 to Y10 through the routing lines 1131 and 1133.

In the display module 1100 according to the embodiment, the touch sensor controller may be disposed on both sides of the display driver circuit to improve the wiring connectivity of the touch screen panel 1110 and lower the die height of the touch screen driver circuit 1120. Accordingly, the number of dies for the touch screen driver circuit 1120 that can be obtained from one wafer can increase. The display module 1100 may use the transmission line for single routing, which can reduce the wiring area, resulting in a decrease in the module size.

Further, in the display module 1100, the receivers 1121 and 1123 may be disposed on both sides of the display driver circuit. Accordingly, it is possible to reduce the deviation between channels of an analog front end (AFE).

In some embodiments, the display module 1100 may further include shielding members between the receiver 1121 and the transmitter 1122 or between the transmission lines and the reception lines. The shielding members are members for preventing electromagnetic interference, and may include shielding lines, shielding layers, and the like.

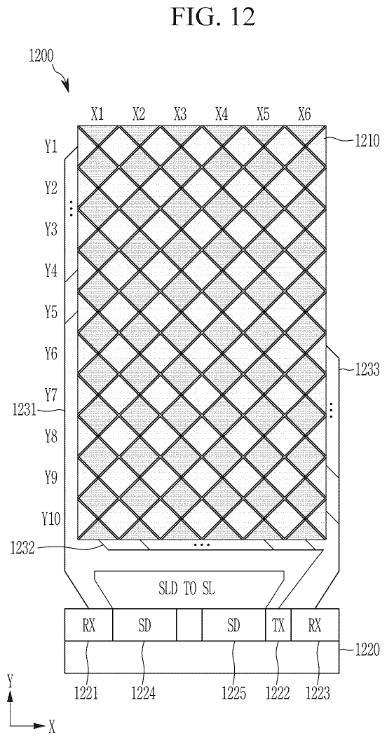

FIG. 12 is a drawing for explaining routing of a display module according to one or more embodiments.

Referring to FIG. 12, a display module 1200 according to one or more embodiments may include a touch screen panel 1210, a touch screen driver circuit 1220, and routing lines 1231 to 1233. The display module 1200 may be the same as the display module 1100 of FIG. 11 except that a transmitter is positioned on the right side, not the left side. The description of FIGS. 1 to 5 may be equally applied to the touch screen panel 1210 and the touch screen driver circuit 1220. Accordingly, a redundant description will not be made.

The touch screen panel 1210 may include a plurality of driving electrodes X1 to X6 and a plurality of receiving electrodes Y1 to Y10. In some embodiments, the numbers of driving electrodes and receiving electrodes that are included in the touch screen panel 1210 may vary depending on the resolution of the touch screen panel 1210. In the display module 1200, transmission lines may be implemented by single routing. In some embodiments, the plurality of driving electrodes X1 to X6 may serve as receiving electrodes, and the plurality of receiving electrodes Y1 to Y10 may serve as driving electrodes.

The touch screen driver circuit 1220 may include a display driver circuit (including, for example, source drivers 1224 and 1225) and a touch sensor controller (including, for example, a transmitter 1222 and receivers 1221 and 1223). The display driver circuit may be disposed in the center (or middle) of the touch screen driver circuit 1220. In some embodiments, the center of the touch screen driver circuit 1220 may not necessarily refer to the exact center.

The touch sensor controller may be disposed on the periphery of the display driver circuit. For example, the receiver 1221 may be disposed on the left side of the display driver circuit, and the transmitter 1222 and the receiver 1223 may be disposed on the right side.

The touch screen panel 1210 and the touch screen driver circuit 1220 may be connected through the routing lines 1231 to 1233. The routing line 1232 may be a transmission line, and the routing lines 1231 and 1233 may be reception lines. In some embodiments, the transmission lines may be implemented by single routing or may be implemented by dual routing. The reception lines may be implemented by single routing. In some embodiments, the receivers that are connected to the reception lines may be disposed on one side or both sides of the display driver circuit.

In FIG. 12, the transmission lines may be implemented by single routing, and the receivers 1221 and 1223 may be disposed on both sides of the display driver circuit. The transmitter 1222 may be disposed on the right side of the display driver circuit. The routing line 1232 may be connected to the plurality of driving electrodes X1 to X6. For example, the routing line 1232 may be connected to the lower sides of the driving electrodes X1 to X6.

The routing lines 1231 and 1233 may be connected to the plurality of receiving electrodes Y1 to Y10. For example, the routing line 1231 may be connected to the receiving electrodes Y1 to Y5, and the routing line 1233 may be connected to the receiving electrodes Y6 to Y10. However, the embodiments are not necessarily limited thereto, and the number of receiving electrodes that are connected to each of the routing lines 1231 and 1233 may be changed. Further, the routing line 1231 may be connected to the left sides of the receiving electrodes Y1 to Y5, and the routing line 1233 may be connected to the right sides of the receiving electrodes Y6 to Y10.

The transmitter 1222 and the receivers 1221 and 1223 may be connected to the electrodes X1 to X6 and Y1 to Y10 through the routing lines 1231 to 1233. For example, the receiver 1221 may be connected to the routing line 1231, the transmitter 1222 may be connected to the routing line 1232, and the receiver 1223 may be connected to the routing line 1233. In other words, the transmitter 1222 may transmit driving signals to the plurality of driving electrodes X1 to X6 through the routing line 1232. The receivers 1221 and 1223 may receive sensing signals from the plurality of receiving electrodes Y1 to Y10 through the routing lines 1231 and 1233.

In the display module 1200 according to the embodiment, the touch sensor controller may be disposed on both sides of the display driver circuit to improve the wiring connectivity of the touch screen panel 1210 and lower the die height of the touch screen driver circuit 1220. Accordingly, the number of dies for the touch screen driver circuit 1220 that can be obtained from one wafer can increase. The display module 1200 may use the transmission line for single routing, which can reduce the wiring area, resulting in a decrease in the module size.

Further, in the display module 1200, the receivers 1221 and 1223 may be disposed on both sides of the display driver circuit. Accordingly, it is possible to reduce the deviation between channels of an analog front end (AFE).

In some embodiments, the display module 1200 may further include shielding members between the transmitter 1222 and the receiver 1223 or between the transmission lines and the reception lines. The shielding members are members for preventing electromagnetic interference, and may include shielding lines, shielding layers, and the like.

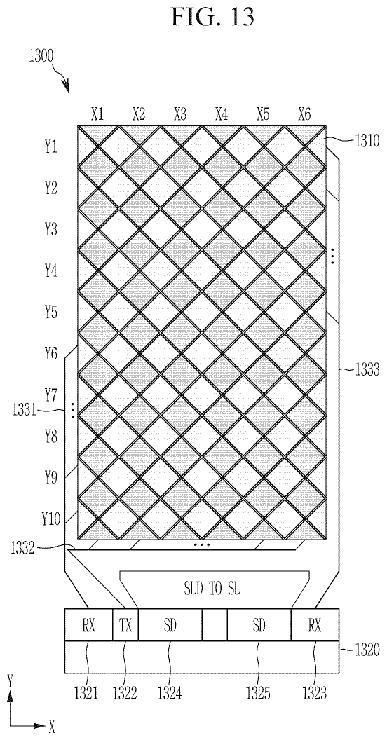

FIG. 13 is a drawing for explaining routing of a display module according to one or more embodiments.

Referring to FIG. 13, a display module 1300 according to one or more embodiments may include a touch screen panel 1310, a touch screen driver circuit 1320, and routing lines 1331 to 1333. The display module 1300 may differ from the display module 1100 of FIG. 11 only in receiving electrodes to which reception lines are connected. The description of FIGS. 1 to 5 may be equally applied to the touch screen panel 1310 and the touch screen driver circuit 1320. Accordingly, a redundant description will not be made.

The touch screen panel 1310 may include a plurality of driving electrodes X1 to X6 and a plurality of receiving electrodes Y1 to Y10. In some embodiments, the numbers of driving electrodes and receiving electrodes that are included in the touch screen panel 1310 may vary depending on the resolution of the touch screen panel 1310. In the display module 1300, transmission lines may be implemented by single routing. In some embodiments, the plurality of driving electrodes X1 to X6 may serve as receiving electrodes, and the plurality of receiving electrodes Y1 to Y10 may serve as driving electrodes.

The touch screen driver circuit 1320 may include a display driver circuit (including, for example, source drivers 1324 and 1325) and a touch sensor controller (including, for example, a transmitter 1322 and receivers 1321 and 1323). The display driver circuit may be disposed in the center (or middle) of the touch screen driver circuit 1320. In some embodiments, the center of the touch screen driver circuit 1320 may not necessarily refer to the exact center.

The touch sensor controller may be disposed on the periphery of the display driver circuit. For example, the receiver 1321 and the transmitter 1322 may be disposed on the left side of the display driver circuit, and the receiver 1323 may be disposed on the right side.

The touch screen panel 1310 and the touch screen driver circuit 1320 may be connected through the routing lines 1331 to 1333. The routing line 1332 may be a transmission line, and the routing lines 1331 and 1333 may be reception lines. In some embodiments, the transmission lines may be implemented by single routing or may be implemented by dual routing. The reception lines may be implemented by single routing. In some embodiments, the receivers that are connected to the reception lines may be disposed on one side or both sides of the display driver circuit.

In FIG. 13, the transmission lines may be implemented by single routing, and the receivers 1321 and 1323 may be disposed on both sides of the display driver circuit. The transmitter 1322 may be disposed on the left side of the display driver circuit. The routing line 1332 may be connected to the plurality of driving electrodes X1 to X6. For example, the routing line 1332 may be connected to the lower sides of the driving electrodes X1 to X6.

The routing lines 1331 and 1333 may be connected to the plurality of receiving electrodes Y1 to Y10. For example, the routing line 1331 may be connected to the left sides of the receiving electrodes Y6 to Y10, and the routing line 1333 may be connected to the right sides of the receiving electrodes Y1 to Y5. However, the embodiments are not necessarily limited thereto, and the number of receiving electrodes that are connected to each of the routing lines 1331 and 1333 may be changed.

The transmitter 1322 and the receivers 1321 and 1323 may be connected to the electrodes X1 to X6 and Y1 to Y10 through the routing lines 1331 to 1333. For example, the receiver 1321 may be connected to the routing line 1331, the transmitter 1322 may be connected to the routing line 1332, and the receiver 1323 may be connected to the routing line 1333. In other words, the transmitter 1322 may transmit driving signals to the plurality of driving electrodes X1 to X6 through the routing line 1332. The receivers 1321 and 1323 may receive sensing signals from the plurality of receiving electrodes Y1 to Y10 through the routing lines 1331 and 1333.

In the display module 1300 according to the embodiment, the touch sensor controller may be disposed on both sides of the display driver circuit to improve the wiring connectivity of the touch screen panel 1310 and lower the die height of the touch screen driver circuit 1320. Accordingly, the number of dies for the touch screen driver circuit 1320 that can be obtained from one wafer can increase. The display module 1300 may use the transmission line for single routing, which can reduce the wiring area, resulting in a decrease in the module size.

Further, in the display module 1300, the receivers 1321 and 1323 may be disposed on both sides of the display driver circuit. Accordingly, it is possible to reduce the deviation between channels of an analog front end (AFE).

In some embodiments, the display module 1300 may further include shielding members between the receiver 1321 and the transmitter 1322 or between the transmission lines and the reception lines. The shielding members are members for preventing electromagnetic interference, and may include shielding lines, shielding layers, and the like.

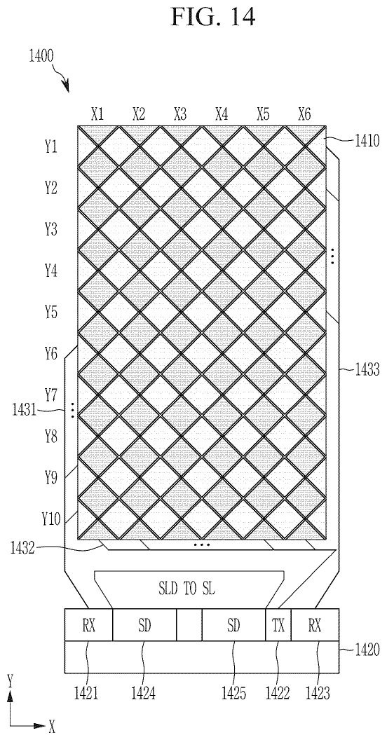

FIG. 14 is a drawing for explaining routing of a display module according to one or more embodiments.

Referring to FIG. 14, a display module 1400 according to one or more embodiments may include a touch screen panel 1410, a touch screen driver circuit 1420, and routing lines 1431 to 1433. The display module 1400 may differ from the display module 1200 of FIG. 12 only in receiving electrodes to which reception lines are connected. The description of FIGS. 1 to 5 may be equally applied to the touch screen panel 1410 and the touch screen driver circuit 1420. Accordingly, a redundant description will not be made.

The touch screen panel 1410 may include a plurality of driving electrodes X1 to X6 and a plurality of receiving electrodes Y1 to Y10. In some embodiments, the numbers of driving electrodes and receiving electrodes that are included in the touch screen panel 1410 may vary depending on the resolution of the touch screen panel 1410. In the display module 1400, transmission lines may be implemented by single routing. In some embodiments, the plurality of driving electrodes X1 to X6 may serve as receiving electrodes, and the plurality of receiving electrodes Y1 to Y10 may serve as driving electrodes.

The touch screen driver circuit 1420 may include a display driver circuit (including, for example, source drivers 1424 and 1425) and a touch sensor controller (including, for example, a transmitter 1422 and receivers 1421 and 1423). The display driver circuit may be disposed in the center (or middle) of the touch screen driver circuit 1420. In some embodiments, the center of the touch screen driver circuit 1420 may not necessarily refer to the exact center.

The touch sensor controller may be disposed on the periphery of the display driver circuit. For example, the receiver 1421 may be disposed on the left side of the display driver circuit, and the transmitter 1422 and the receiver 1423 may be disposed on the right side.

The touch screen panel 1410 and the touch screen driver circuit 1420 may be connected through the routing lines 1431 to 1433. The routing line 1432 may be a transmission line, and the routing lines 1431 and 1433 may be reception lines. In some embodiments, the transmission lines may be implemented by single routing or may be implemented by dual routing. The reception lines may be implemented by single routing. In some embodiments, the receivers that are connected to the reception lines may be disposed on one side or both sides of the display driver circuit.

In FIG. 14, the transmission lines may be implemented by single routing, and the receivers 1421 and 1423 may be disposed on both sides of the display driver circuit. The transmitter 1422 may be disposed on the right side of the display driver circuit. The routing line 1432 may be connected to the plurality of driving electrodes X1 to X6. For example, the routing line 1432 may be connected to the lower sides of the driving electrodes X1 to X6.

The routing lines 1431 and 1433 may be connected to the plurality of receiving electrodes Y1 to Y10. For example, the routing line 1431 may be connected to the left sides of the receiving electrodes Y6 to Y10, and the routing line 1433 may be connected to the right sides of the receiving electrodes Y1 to Y5. However, the embodiments are not necessarily limited thereto, and the number of receiving electrodes that are connected to each of the routing lines 1431 and 1433 may be changed.

The transmitter 1422 and the receivers 1421 and 1423 may be connected to the electrodes X1 to X6 and Y1 to Y10 through the routing lines 1431 to 1433. For example, the receiver 1421 may be connected to the routing line 1431, the transmitter 1422 may be connected to the routing line 1432, and the receiver 1423 may be connected to the routing line 1433. In other words, the transmitter 1422 may transmit driving signals to the plurality of driving electrodes X1 to X6 through the routing line 1432. The receivers 1421 and 1423 may receive sensing signals from the plurality of receiving electrodes Y1 to Y10 through the routing lines 1431 and 1433.

In the display module 1400 according to the embodiment, the touch sensor controller may be disposed on both sides of the display driver circuit to improve the wiring connectivity of the touch screen panel 1410 and lower the die height of the touch screen driver circuit 1420. Accordingly, the number of dies for the touch screen driver circuit 1420 that can be obtained from one wafer can increase. The display module 1400 may use the transmission line for single routing, which can reduce the wiring area, resulting in a decrease in the module size.

Further, in the display module 1400, the receivers 1421 and 1423 may be disposed on both sides of the display driver circuit. Accordingly, it is possible to reduce the deviation between channels of an analog front end (AFE).

In some embodiments, the display module 1400 may further include shielding members between the transmitter 1422 and the receiver 1423 or between the transmission lines and the reception lines. The shielding members are members for preventing electromagnetic interference, and may include shielding lines, shielding layers, and the like.

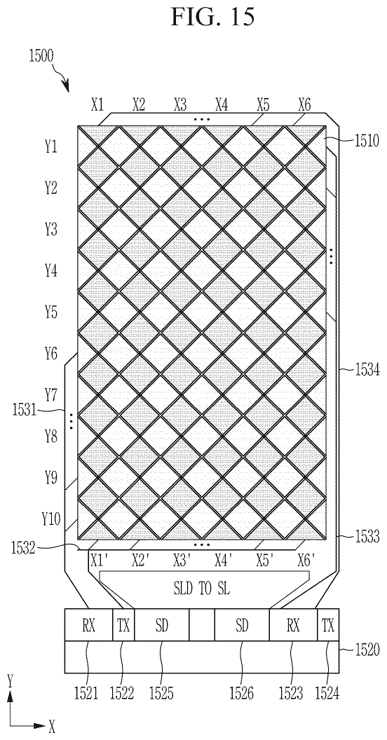

FIG. 15 is a drawing for explaining routing of a display module according to one or more embodiments.

Referring to FIG. 15, a display module 1500 according to one or more embodiments may include a touch screen panel 1510, a touch screen driver circuit 1520, and routing lines 1531 to 1534. The display module 1500 may differ from the display module 1000 of FIG. 10 only in receiving electrodes to which reception lines are connected. The description of FIGS. 1 to 5 may be equally applied to the touch screen panel 1510 and the touch screen driver circuit 1520. Accordingly, a redundant description will not be made.

The touch screen panel 1510 may include a plurality of driving electrodes X1 to X6 and X1′ to X6′ and a plurality of receiving electrodes Y1 to Y10. In some embodiments, the numbers of driving electrodes and receiving electrodes that are included in the touch screen panel 1510 may vary depending on the resolution of the touch screen panel 1510. In some embodiments, the plurality of driving electrodes X1 to X6 and X1′ to X6′ may serve as receiving electrodes, and the plurality of receiving electrodes Y1 to Y10 may serve as driving electrodes.

The touch screen driver circuit 1520 may include a display driver circuit (including, for example, source drivers 1525 and 1526) and a touch sensor controller (including, for example, transmitters 1522 and 1524 and receivers 1521 and 1523). The display driver circuit may be disposed in the center (or middle) of the touch screen driver circuit 1520. In some embodiments, the center of the touch screen driver circuit 1520 may not necessarily refer to the exact center.

The touch sensor controller may be disposed on the periphery of the display driver circuit. For example, the receiver 1521 and the transmitter 1522 may be disposed on the left side of the display driver circuit, and the receiver 1523 and the transmitter 1524 may be disposed on the right side.

The touch screen panel 1510 and the touch screen driver circuit 1520 may be connected through the routing lines 1531 to 1534. The routing lines 1532 and 1534 may be transmission lines, and the routing lines 1531 and 1533 may be reception lines. In some embodiments, the transmission lines may be implemented by single routing or may be implemented by dual routing. The reception lines may be implemented by single routing. In some embodiments, the receivers that are connected to the reception lines may be disposed on one side or both sides of the display driver circuit.

In FIG. 15, the transmission lines may be implemented by dual routing, and the transmitters 1522 and 1524 and the receivers 1521 and 1523 may be disposed on both sides of the display driver circuit. The routing lines 1532 and 1534 may be connected to the plurality of driving electrodes X1 to X6 and X1′ to X6′. For example, the routing line 1532 may be connected to the lower sides of the driving electrodes X1′ to X6′, and the routing line 1534 may be connected to the upper sides of the driving electrodes X1 to X6.

The routing lines 1531 and 1533 may be connected to the plurality of receiving electrodes Y1 to Y10. For example, the routing line 1531 may be connected to the left sides of the receiving electrodes Y6 to Y10, and the routing line 1533 may be connected to the right sides of the receiving electrodes Y1 to Y5. However, the embodiments are not necessarily limited thereto, and the number of receiving electrodes that are connected to each of the routing lines 1531 and 1533 may be changed.

The transmitters 1522 and 1524 and the receivers 1521 and 1523 may be connected to the electrodes X1 to X6, X1′ to X6′, and Y1 to Y10 through the routing lines 1531 to 1534. For example, the receiver 1521 may be connected to the routing line 1531, the transmitter 1522 may be connected to the routing line 1532, the receiver 1523 may be connected to the routing line 1533, and the transmitter 1524 may be connected to the routing line 1534. In other words, the transmitters 1522 and 1524 may transmit driving signals to the plurality of driving electrodes X1 to X6 and X1′ to X6′ through the routing lines 1532 and 1534. The receivers 1521 and 1523 may receive sensing signals from the plurality of receiving electrodes Y1 to Y10 through the routing lines 1531 and 1533.

In the display module 1500 according to the embodiment, the transmitter and receiver sets may be disposed on both sides of the display driver circuit to improve the wiring connectivity of the touch screen panel 1510 and lower the die height of the touch screen driver circuit 1520. Accordingly, the number of dies for the touch screen driver circuit 1520 that can be obtained from one wafer can increase.

The display module 1500 may include the transmission lines for dual routing, resulting in a decrease in the resistance of the wiring. Accordingly, the time constant can decrease and the settling time can shorten. Further, in the display module 1500, the receivers 1521 and 1523 may be disposed on both sides of the display driver circuit. Accordingly, it is possible to reduce the deviation between channels of an analog front end (AFE).

In some embodiments, the display module 1500 may further include shielding members between the transmitters 1522 and 1524 and the receivers 1521 and 1523 or between the transmission lines and the reception lines. The shielding members are members for preventing electromagnetic interference, and may include shielding lines, shielding layers, and the like.

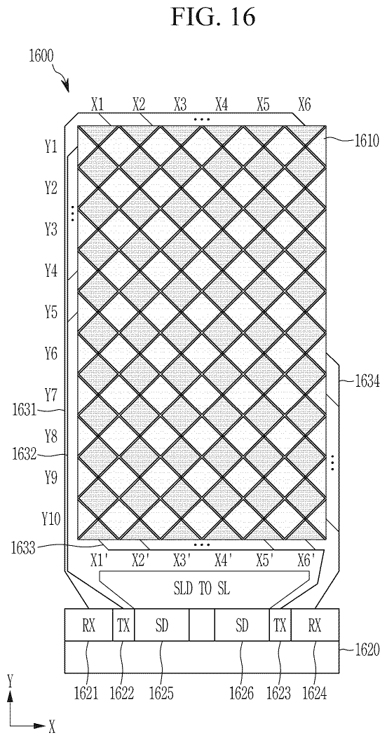

FIG. 16 is a drawing for explaining routing of a display module according to one or more embodiments.

Referring to FIG. 16, a display module 1600 according to one or more embodiments may include a touch screen panel 1610, a touch screen driver circuit 1620, and routing lines 1631 to 1634. The description of FIGS. 1 to 5 may be equally applied to the touch screen panel 1610 and the touch screen driver circuit 1620. Accordingly, a redundant description will not be made.

The touch screen panel 1610 may include a plurality of driving electrodes X1 to X6 and X1′ to X6′ and a plurality of receiving electrodes Y1 to Y10. In some embodiments, the numbers of driving electrodes and receiving electrodes that are included in the touch screen panel 1610 may vary depending on the resolution of the touch screen panel 1610. In some embodiments, the plurality of driving electrodes X1 to X6 and X1′ to X6′ may serve as receiving electrodes, and the plurality of receiving electrodes Y1 to Y10 may serve as driving electrodes.

The touch screen driver circuit 1620 may include a display driver circuit (including, for example, source drivers 1625 and 1626) and a touch sensor controller (including, for example, transmitters 1621 and 1623 and receivers 1622 and 1624). The display driver circuit may be disposed in the center (or middle) of the touch screen driver circuit 1620. In some embodiments, the center of the touch screen driver circuit 1620 may not necessarily refer to the exact center.

The touch sensor controller may be disposed on the periphery of the display driver circuit. For example, the transmitter 1621 and the receiver 1622 may be disposed on the left side of the display driver circuit, and the transmitter 1623 and the receiver 1624 may be disposed on the right side.

The touch screen panel 1610 and the touch screen driver circuit 1620 may be connected through the routing lines 1631 to 1634. The routing lines 1631 and 1633 may be transmission lines, and the routing lines 1632 and 1634 may be reception lines. In some embodiments, the transmission lines may be implemented by single routing or may be implemented by dual routing. The reception lines may be implemented by single routing. In some embodiments, the receivers that are connected to the reception lines may be disposed on one side or both sides of the display driver circuit.

In FIG. 16, the transmission lines may be implemented by dual routing, and the transmitters 1621 and 1623 and the receivers 1622 and 1624 may be disposed on both sides of the display driver circuit. The routing lines 1631 and 1633 may be connected to the plurality of driving electrodes X1 to X6 and X1′ to X6′. For example, the routing line 1631 may be connected to the upper sides of the driving electrodes X1 to X6, and the routing line 1633 may be connected to the lower sides of the driving electrodes X1′ to X6′.

The routing lines 1632 and 1634 may be connected to the plurality of receiving electrodes Y1 to Y10. For example, the routing line 1632 may be connected to the left sides of the receiving electrodes Y1 to Y5, and the routing line 1634 may be connected to the right sides of the receiving electrodes Y6 to Y10. However, the embodiments are not necessarily limited thereto, and the number of receiving electrodes that are connected to each of the routing lines 1632 and 1634 may be changed.

The transmitters 1621 and 1623 and the receivers 1622 and 1624 may be connected to the electrodes X1 to X6, X1′ to X6′, and Y1 to Y10 through the routing lines 1631 to 1634. For example, the transmitter 1621 may be connected to the routing line 1631, the receiver 1622 may be connected to the routing line 1632, the transmitter 1623 may be connected to the routing line 1633, and the receiver 1624 may be connected to the routing line 1634. In other words, the transmitters 1621 and 1623 may transmit driving signals to the plurality of driving electrodes X1 to X6 and X1′ to X6′ through the routing lines 1631 and 1633. The receivers 1622 and 1624 may receive sensing signals from the plurality of receiving electrodes Y1 to Y10 through the routing lines 1632 and 1634.

In the display module 1600 according to the embodiment, the transmitter and receiver sets may be disposed on both sides of the display driver circuit to improve the wiring connectivity of the touch screen panel 1610 and lower the die height of the touch screen driver circuit 1620. Accordingly, the number of dies for the touch screen driver circuit 1620 that can be obtained from one wafer can increase.

The display module 1600 may include the transmission lines for dual routing, resulting in a decrease in the resistance of the wiring. Accordingly, the time constant can decrease and the settling time can shorten. Further, in the display module 1600, the receivers 1622 and 1624 may be disposed on both sides of the display driver circuit. Accordingly, it is possible to reduce the deviation between channels of an analog front end (AFE).

In some embodiments, the display module 1600 may further include shielding members between the transmitters 1621 and 1623 and the receivers 1622 and 1624 or between the transmission lines and the reception lines. The shielding members are members for preventing electromagnetic interference, and may include shielding lines, shielding layers, and the like.

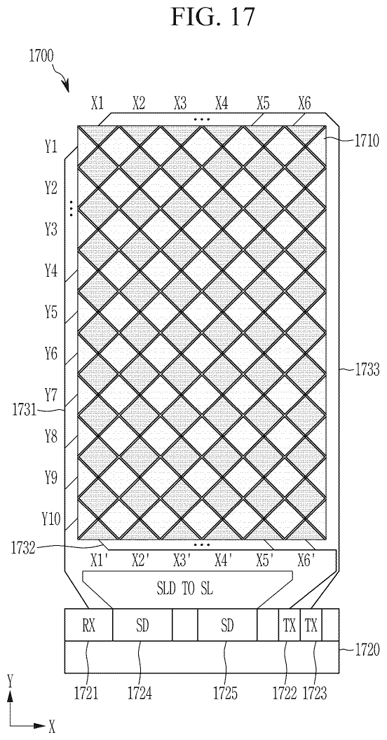

FIG. 17 is a drawing for explaining routing of a display module according to one or more embodiments.

Referring to FIG. 17, a display module 1700 according to one or more embodiments may include a touch screen panel 1710, a touch screen driver circuit 1720, and routing lines 1731 to 1733. The description of FIGS. 1 to 5 may be equally applied to the touch screen panel 1710 and the touch screen driver circuit 1720. Accordingly, a redundant description will not be made.

The touch screen panel 1710 may include a plurality of driving electrodes X1 to X6 and X1′ to X6′ and a plurality of receiving electrodes Y1 to Y10. In some embodiments, the numbers of driving electrodes and receiving electrodes that are included in the touch screen panel 1710 may vary depending on the resolution of the touch screen panel 1710. In some embodiments, the plurality of driving electrodes X1 to X6 and X1′ to X6′ may serve as receiving electrodes, and the plurality of receiving electrodes Y1 to Y10 may serve as driving electrodes.

The touch screen driver circuit 1720 may include a display driver circuit (including, for example, source drivers 1724 and 1725) and a touch sensor controller (including, for example, a receiver 1721 and transmitters 1722 and 1723). The display driver circuit may be disposed in the center (or middle) of the touch screen driver circuit 1720. In some embodiments, the center of the touch screen driver circuit 1720 may not necessarily refer to the exact center.

The touch sensor controller may be disposed on the periphery of the display driver circuit. For example, the receiver 1721 may be disposed on the left side of the display driver circuit, and the transmitters 1722 and 1723 may be disposed on the right side.

The touch screen panel 1710 and the touch screen driver circuit 1720 may be connected through the routing lines 1731 to 1733. The routing lines 1732 and 1733 may be transmission lines, and the routing line 1731 may be a reception line. In some embodiments, the transmission lines may be implemented by single routing or may be implemented by dual routing. The reception lines may be implemented by single routing. In some embodiments, the receivers that are connected to the reception lines may be disposed on one side or both sides of the display driver circuit.

In FIG. 17, the transmission lines may be implemented by dual routing, and the receiver 1721 and the transmitters 1722 and 1723 may be disposed on both sides of the display driver circuit. The routing lines 1732 and 1733 may be connected to the plurality of driving electrodes X1 to X6 and X1′ to X6′. For example, the routing line 1732 may be connected to the lower sides of the driving electrodes X1′ to X6′, and the routing line 1733 may be connected to the upper sides of the driving electrodes X1 to X6.

The routing line 1731 may be connected to the left sides of the plurality of receiving electrodes Y1 to Y10.

The receiver 1721 and the transmitters 1722 and 1723 may be connected to the electrodes X1 to X6, X1′ to X6′, and Y1 to Y10 through the routing lines 1731 to 1733. For example, the receiver 1721 may be connected to the routing line 1731, the transmitter 1722 may be connected to the routing line 1732, and the transmitter 1723 may be connected to the routing line 1733. In other words, the transmitters 1722 and 1723 may transmit driving signals to the plurality of driving electrodes X1 to X6 and X1′ to X6′ through the routing lines 1732 and 1733. The receiver 1721 may receive sensing signals from the plurality of receiving electrodes Y1 to Y10 through the routing line 1731.

In the display module 1700 according to the embodiment, the touch sensor controller may be disposed on both sides of the display driver circuit to improve the wiring connectivity of the touch screen panel 1710 and lower the die height of the touch screen driver circuit 1720. Accordingly, the number of dies for the touch screen driver circuit 1720 that can be obtained from one wafer can increase.

The display module 1700 may include the transmission lines for dual routing, which can reduce the resistance of wiring. Accordingly, the time constant can decrease, and the settling time can shorten. Further, in the display module 1700, the receiver 1721 may be disposed on one side of the display driver circuit (for example, the left side), which can reduce the wiring area of the reception line, resulting in a decrease in the module size.

In some embodiments, the display module 1700 may further include shielding members between the transmission lines and the reception lines. The shielding members are members for preventing electromagnetic interference, and may include shielding lines, shielding layers, and the like.

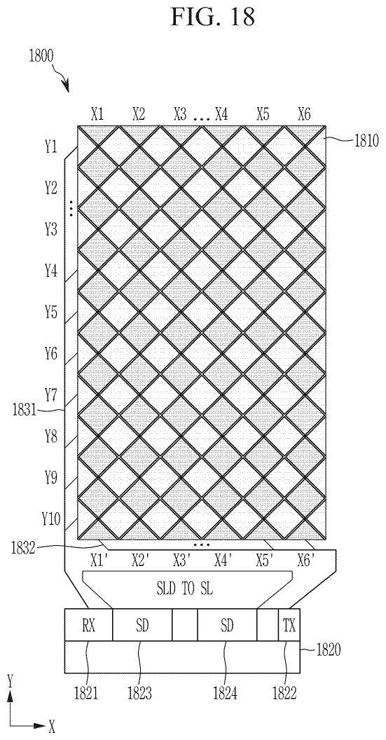

FIG. 18 is a drawing for explaining routing of a display module according to one or more embodiments.

Referring to FIG. 18, a display module 1800 according to one or more embodiments may include a touch screen panel 1810, a touch screen driver circuit 1820, and routing lines 1831 and 1832. The display module 1800 may be the same as the display module 1700 of FIG. 17 except that it includes transmission lines for single routing in place of the transmission lines for dual routing. The description of FIGS. 1 to 5 may be equally applied to the touch screen panel 1810 and the touch screen driver circuit 1820. Accordingly, a redundant description will not be made.

The touch screen panel 1810 may include a plurality of driving electrodes X1 to X6 and a plurality of receiving electrodes Y1 to Y10. In some embodiments, the numbers of driving electrodes and receiving electrodes that are included in the touch screen panel 1810 may vary depending on the resolution of the touch screen panel 1810. In some embodiments, the plurality of driving electrodes X1 to X6 may serve as receiving electrodes, and the plurality of receiving electrodes Y1 to Y10 may serve as driving electrodes.

The touch screen driver circuit 1820 may include a display driver circuit (including, for example, source drivers 1823 and 1824) and a touch sensor controller (including, for example, a receiver 1821 and a transmitter 1822). The display driver circuit may be disposed in the center (or middle) of the touch screen driver circuit 1820. In some embodiments, the center of the touch screen driver circuit 1820 may not necessarily refer to the exact center.

The touch sensor controller may be disposed on the periphery of the display driver circuit. For example, the receiver 1821 may be disposed on the left side of the display driver circuit, and the transmitter 1822 may be disposed on the right side. The touch screen panel 1810 and the touch screen driver circuit 1820

may be connected through the routing lines 1831 and 1832. The routing line 1831 may be a reception line, and the routing line 1832 may be a transmission line. In some embodiments, the transmission lines may be implemented by single routing or may be implemented by dual routing. The reception lines may be implemented by single routing. In some embodiments, the receiver that is connected to the reception line may be disposed on one side or both sides of the display driver circuit.

In FIG. 18, the transmission lines may be implemented by single routing, and the receiver 1821 and the transmitter 1822 may be disposed on both sides of the display driver circuit. The routing line 1831 may be connected to the left sides of the plurality of receiving electrodes Y1 to Y10. The routing line 1832 may be connected to the lower sides of the plurality of driving electrodes X1 to X6.

The receiver 1821 and the transmitter 1822 may be connected to the electrodes X1 to X6 and Y1 to Y10 through the routing lines 1831 and 1832. For example, the receiver 1821 may be connected to the routing line 1831, and the transmitter 1822 may be connected to the routing line 1832. In other words, the transmitter 1822 may transmit driving signals to the plurality of driving electrodes X1 to X6 through the routing line 1832. The receiver 1821 may receive sensing signals from the plurality of receiving electrodes Y1 to Y10 through the routing line 1831.

In the display module 1800 according to the embodiment, the touch sensor controller may be disposed on both sides of the display driver circuit to improve the wiring connectivity of the touch screen panel 1810 and lower the die height of the touch screen driver circuit 1820. Accordingly, the number of dies for the touch screen driver circuit 1820 that can be obtained from one wafer can increase.

Further, the display module 1800 may use the transmission line for single routing, which can reduce the wiring area, resulting in a decrease in the module size. In the display module 1800, the receiver 1821 may be disposed on one side of the display driver circuit (for example, the left side), which can reduce the wiring area of the reception line, resulting in a decrease in the module size.

In some embodiments, the display module 1800 may further include shielding members between the transmission lines and the reception lines. The shielding members are members for preventing electromagnetic interference, and may include shielding lines, shielding layers, and the like.

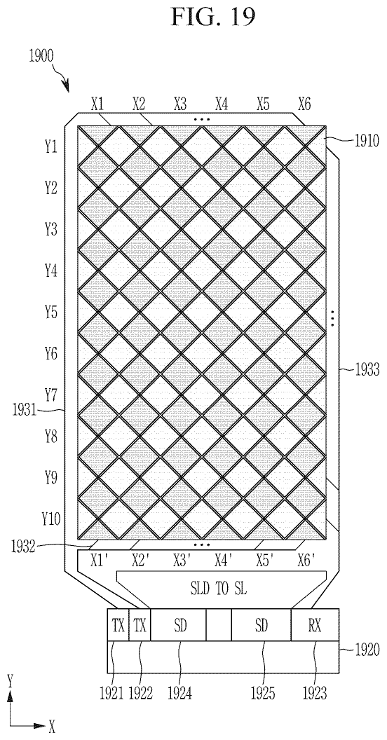

FIG. 19 is a drawing for explaining routing of a display module according to one or more embodiments.

Referring to FIG. 19, a display module 1900 according to one or more embodiments may include a touch screen panel 1910, a touch screen driver circuit 1920, and routing lines 1931 to 1933. The display module 1900 may be the same as the display module 1700 of FIG. 17 except that a region where transmitters are disposed is on the left side of a display driver circuit and a region where a receiver is disposed is on the right side of the display driver circuit. The description of FIGS. 1 to 5 may be equally applied to the touch screen panel 1910 and the touch screen driver circuit 1920. Accordingly, a redundant description will not be made.

The touch screen panel 1910 may include a plurality of driving electrodes X1 to X6 and X1′ to X6′ and a plurality of receiving electrodes Y1 to Y10. In some embodiments, the numbers of driving electrodes and receiving electrodes that are included in the touch screen panel 1910 may vary depending on the resolution of the touch screen panel 1910. In some embodiments, the plurality of driving electrodes X1 to X6 and X1′ to X6′ may serve as receiving electrodes, and the plurality of receiving electrodes Y1 to Y10 may serve as driving electrodes.

The touch screen driver circuit 1920 may include a display driver circuit (including, for example, source drivers 1924 and 1925) and a touch sensor controller (including, for example, a receiver 1923 and transmitters 1921 and 1922). The display driver circuit may be disposed in the center (or middle) of the touch screen driver circuit 1920. In some embodiments, the center of the touch screen driver circuit 1920 may not necessarily refer to the exact center.

The touch sensor controller may be disposed on the periphery of the display driver circuit. For example, the transmitters 1921 and 1922 may be disposed on the left side of the display driver circuit, and the receiver 1923 may be disposed on the right side.

The touch screen panel 1910 and the touch screen driver circuit 1920 may be connected through the routing lines 1931 to 1933. The routing lines 1931 and 1932 may be transmission lines, and the routing line 1933 may be a reception line. In some embodiments, the transmission lines may be implemented by single routing or may be implemented by dual routing. The reception lines may be implemented by single routing. In some embodiments, the receivers that are connected to the reception lines may be disposed on one side or both sides of the display driver circuit.

In FIG. 19, the transmission lines may be implemented by dual routing, and the transmitters 1921 and 1922 and the receiver 1923 may be disposed on both sides of the display driver circuit. The routing lines 1931 and 1932 may be connected to the plurality of driving electrodes X1 to X6 and X1′ to X6′. For example, the routing line 1931 may be connected to the upper sides of the driving electrodes X1 to X6, and the routing line 1932 may be connected to the lower sides of the driving electrodes X1′ to X6′.

The routing line 1933 may be connected to the right sides of the plurality of receiving electrodes Y1 to Y10.

The transmitters 1921 and 1922 and the receiver 1923 may be connected to the electrodes X1 to X6, X1′ to X6′, and Y1 to Y10 through the routing lines 1931 to 1933. For example, the transmitter 1921 may be connected to the routing line 1931, the transmitter 1922 may be connected to the routing line 1932, and the receiver 1923 may be connected to the routing line 1933. In other words, the transmitters 1921 and 1922 may transmit driving signals to the plurality of driving electrodes X1 to X6 and X1′ to X6′ through the routing lines 1931 and 1932. The receiver 1923 may receive sensing signals from the plurality of receiving electrodes Y1 to Y10 through the routing line 1933.

In the display module 1900 according to the embodiment, the touch sensor controller may be disposed on both sides of the display driver circuit to improve the wiring connectivity of the touch screen panel 1910 and lower the die height of the touch screen driver circuit 1920. Accordingly, the number of dies for the touch screen driver circuit 1920 that can be obtained from one wafer can increase.

The display module 1900 may include the transmission lines for dual routing, which can reduce the resistance of wiring. Accordingly, the time constant can decrease, and the settling time can shorten. Further, in the display module 1900, the receiver 1923 may be disposed on one side of the display driver circuit (for example, the right side), which can reduce the wiring area of the reception line, resulting in a decrease in the module size.

In some embodiments, the display module 1900 may further include shielding members between the transmission lines and the reception line. The shielding members are members for preventing electromagnetic interference, and may include shielding lines, shielding layers, and the like.

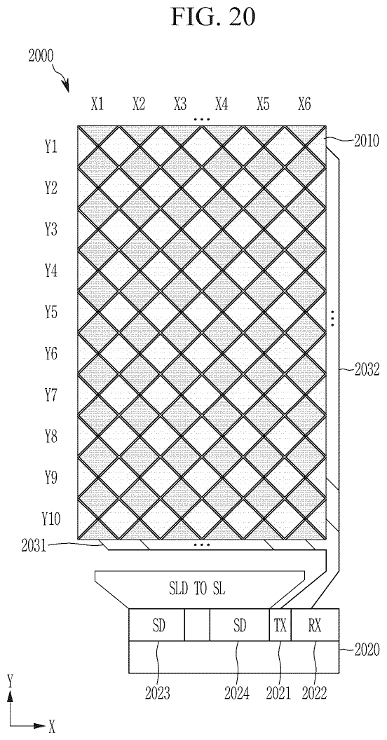

FIG. 20 is a drawing for explaining routing of a display module according to one or more embodiments.

Referring to FIG. 20, a display module 2000 according to one or more embodiments may include a touch screen panel 2010, a touch screen driver circuit 2020, and routing lines 2031 and 2032. The display module 2000 may be the same as the display module 1800 of FIG. 18 except that a region where a receiver is disposed is on the right side of a display driver circuit. The description of FIGS. 1 to 5 may be equally applied to the touch screen panel 2010 and the touch screen driver circuit 2020. Accordingly, a redundant description will not be made.

The touch screen panel 2010 may include a plurality of driving electrodes X1 to X6 and a plurality of receiving electrodes Y1 to Y10. In some embodiments, the numbers of driving electrodes and receiving electrodes that are included in the touch screen panel 2010 may vary depending on the resolution of the touch screen panel 2010. In some embodiments, the plurality of driving electrodes X1 to X6 may serve as receiving electrodes, and the plurality of receiving electrodes Y1 to Y10 may serve as driving electrodes.

The touch screen driver circuit 2020 may include a display driver circuit (including, for example, source drivers 2023 and 2024) and a touch sensor controller (including, for example, a transmitter 2021 and a receiver 2022). The display driver circuit may be disposed in the center (or middle) of the touch screen driver circuit 2020. In some embodiments, the center of the touch screen driver circuit 2020 may not necessarily refer to the exact center.

The touch sensor controller may be disposed on the periphery of the display driver circuit. For example, the transmitter 2021 and the receiver 2022 may be disposed on the right side of the display driver circuit.

The touch screen panel 2010 and the touch screen driver circuit 2020 may be connected through the routing lines 2031 and 2032. The routing line 2031 may be a transmission line, and the routing line 2032 may be a reception line. In some embodiments, the transmission lines may be implemented by single routing or may be implemented by dual routing. The reception lines may be implemented by single routing. In some embodiments, the receiver that is connected to the reception line may be disposed on one side or both sides of the display driver circuit.

In FIG. 20, the transmission line may be implemented by single routing, and the transmitter 2021 and the receiver 2022 may be disposed on one side of the display driver circuit (for example, the right side). The routing line 2031 may be connected to the lower sides of the plurality of driving electrodes X1 to X6. The routing line 2032 may be connected to the right sides of the plurality of receiving electrodes Y1 to Y10. In some embodiments, the routing line 2031 may be connected to the upper sides of the plurality of driving electrodes X1 to X6. In this case, the transmitter 2021 may be disposed on the right side of the receiver 2022.

The transmitter 2021 and the receiver 2022 may be connected to the electrodes X1 to X6 and Y1 to Y10 through the routing lines 2031 and 2032. For example, the transmitter 2021 may be connected to the routing line 2031, and the receiver 2022 may be connected to the routing line 2032. In other words, the transmitter 2021 may transmit driving signals to the plurality of driving electrodes X1 to X6 through the routing line 2031. The receiver 2022 may receive sensing signals from the plurality of receiving electrodes Y1 to Y10 through the routing line 2032.

In the display module 2000 according to the embodiment, the touch sensor controller may be disposed on one side of the display driver circuit to improve the wiring connectivity of the touch screen panel 2010 and lower the die height of the touch screen driver circuit 2020. Accordingly, the number of dies for the touch screen driver circuit 2020 that can be obtained from one wafer can increase.

Further, the display module 2000 may use the transmission line for single routing, which can reduce the wiring area, resulting in a decrease in the module size. In the display module 2000, the transmitter 2021 and the receiver 2022 may be disposed on one side of the display driver circuit, which can reduce the wiring area of the routing lines 2031 and 2032, resulting in a decrease in the module size.

In some embodiments, the display module 2000 may further include shielding members between the transmitter 2021 and the receiver 2022 or between the transmission line and the reception line. The shielding members are members for preventing electromagnetic interference, and may include shielding lines, shielding layers, and the like.

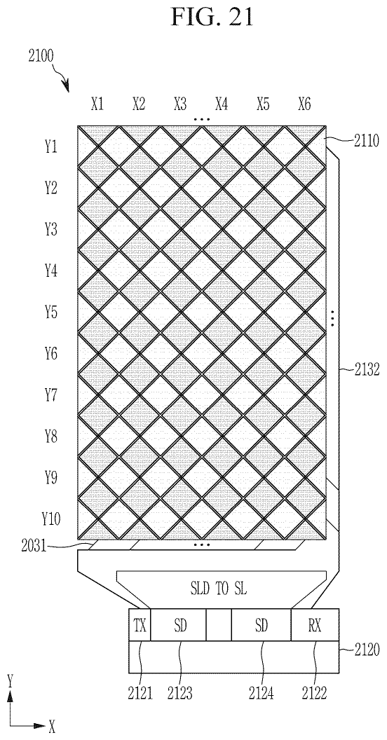

FIG. 21 is a drawing for explaining routing of a display module according to one or more embodiments.

Referring to FIG. 21, a display module 2100 according to one or more embodiments may include a touch screen panel 2110, a touch screen driver circuit 2120, and routing lines 2131 and 2132. The display module 2100 may be the same as the display module 2000 of FIG. 20 except that a region where a transmitter is disposed is on the left side of a display driver circuit. The description of FIGS. 1 to 5 may be equally applied to the touch screen panel 2110 and the touch screen driver circuit 2120. Accordingly, a redundant description will not be made.

The touch screen panel 2110 may include a plurality of driving electrodes X1 to X6 and a plurality of receiving electrodes Y1 to Y10. In some embodiments, the numbers of driving electrodes and receiving electrodes that are included in the touch screen panel 2110 may vary depending on the resolution of the touch screen panel 2110. In some embodiments, the plurality of driving electrodes X1 to X6 may serve as receiving electrodes, and the plurality of receiving electrodes Y1 to Y10 may serve as driving electrodes.

The touch screen driver circuit 2120 may include a display driver circuit (including, for example, source drivers 2123 and 2124) and a touch sensor controller (including, for example, a transmitter 2121 and a receiver 2122). The display driver circuit may be disposed in the center (or middle) of the touch screen driver circuit 2120. In some embodiments, the center of the touch screen driver circuit 2120 may not necessarily refer to the exact center.

The touch sensor controller may be disposed on the periphery of the display driver circuit. For example, the transmitter 2121 may be disposed on the left side of the display driver circuit, and the receiver 2122 may be disposed on the right side of the display driver circuit.

The touch screen panel 2110 and the touch screen driver circuit 2120 may be connected through the routing lines 2131 and 2132. The routing line 2131 may be a transmission line, and the routing line 2132 may be a reception line. In some embodiments, the transmission lines may be implemented by single routing or may be implemented by dual routing. The reception lines may be implemented by single routing. In some embodiments, the receiver that is connected to the reception line may be disposed on one side or both sides of the display driver circuit.

In FIG. 21, the transmission line may be implemented by single routing, and the transmitter 2121 and the receiver 2122 may be disposed on both sides of the display driver circuit. The routing line 2131 may be connected to the lower sides of the plurality of driving electrodes X1 to X6. The routing line 2132 may be connected to the right sides of the plurality of receiving electrodes Y1 to Y10. In some embodiments, the routing line 2131 may be connected to the upper sides of the plurality of driving electrodes X1 to X6.

The transmitter 2121 and the receiver 2122 may be connected to the electrodes X1 to X6 and Y1 to Y10 through the routing lines 2131 and 2132. For example, the transmitter 2121 may be connected to the routing line 2131, and the receiver 2122 may be connected to the routing line 2132. In other words, the transmitter 2121 may transmit driving signals to the plurality of driving electrodes X1 to X6 through the routing line 2131. The receiver 2122 may receive sensing signals from the plurality of receiving electrodes Y1 to Y10 through the routing line 2132.

In the display module 2100 according to the embodiment, the touch sensor controller may be disposed on both sides of the display driver circuit to improve the wiring connectivity of the touch screen panel 2110 and lower the die height of the touch screen driver circuit 2120. Accordingly, the number of dies for the touch screen driver circuit 2120 that can be obtained from one wafer can increase.

Further, the display module 2100 may use the transmission line for single routing, which can reduce the wiring area, resulting in a decrease in the module size. In the display module 2100, the receiver 2122 may be disposed on one side of the display driver circuit (for example, the right side), which can reduce the wiring area of the reception line, resulting in a decrease in the module size.

In some embodiments, the display module 2100 may further include shielding members between the transmission line and the reception line. The shielding members are members for preventing electromagnetic interference, and may include shielding lines, shielding layers, and the like.

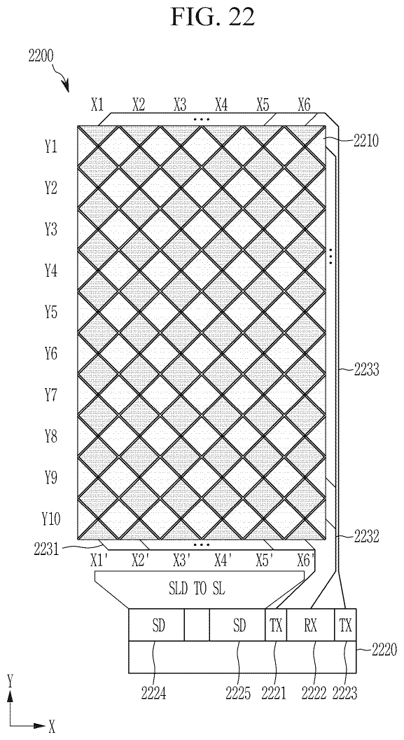

FIG. 22 is a drawing for explaining routing of a display module according to one or more embodiments.

Referring to FIG. 22, a display module 2200 according to one or more embodiments may include a touch screen panel 2210, a touch screen driver circuit 2220, and routing lines 2231 to 2233. The display module 2200 may be the same as the display module 1700 of FIG. 17 except that a region where a receiver is disposed is on the right side of a display driver circuit. The description of FIGS. 1 to 5 may be equally applied to the touch screen panel 2210 and the touch screen driver circuit 2220. Accordingly, a redundant description will not be made.

The touch screen panel 2210 may include a plurality of driving electrodes X1 to X6 and X1′ to X6′ and a plurality of receiving electrodes Y1 to Y10. In some embodiments, the numbers of driving electrodes and receiving electrodes that are included in the touch screen panel 2210 may vary depending on the resolution of the touch screen panel 2210. In some embodiments, the plurality of driving electrodes X1 to X6 and X1′ to X6′ may serve as receiving electrodes, and the plurality of receiving electrodes Y1 to Y10 may serve as driving electrodes.

The touch screen driver circuit 2220 may include a display driver circuit (including, for example, source drivers 2224 and 2225) and a touch sensor controller (including, for example, a receiver 2222 and transmitters 2221 and 2223). The display driver circuit may be disposed in the center (or middle) of the touch screen driver circuit 2220. In some embodiments, the center of the touch screen driver circuit 2220 may not necessarily refer to the exact center.

The touch sensor controller may be disposed on the periphery of the display driver circuit. For example, the transmitters 2221 and 2223 and the receiver 2222 may be disposed on the right side of the display driver circuit.

The touch screen panel 2210 and the touch screen driver circuit 2220 may be connected through the routing lines 2231 to 2233. The routing lines 2231 and 2233 may be transmission lines, and the routing line 2232 may be a reception line. In some embodiments, the transmission lines may be implemented by single routing or may be implemented by dual routing. The reception lines may be implemented by single routing. In some embodiments, the receivers that are connected to the reception lines may be disposed on one side or both sides of the display driver circuit.

In FIG. 22, the transmission lines may be implemented by dual routing, and the transmitters 2221 and 2223 and the receiver 2222 may be disposed on both sides of the display driver circuit. The routing lines 2231 and 2233 may be connected to the plurality of driving electrodes X1 to X6 and X1′ to X6′. For example, the routing line 2231 may be connected to the lower sides of the driving electrodes X1′ to X6′, and the routing line 2233 may be connected to the upper sides of the driving electrodes X1 to X6.

The routing line 2232 may be connected to the right sides of the plurality of receiving electrodes Y1 to Y10.

The transmitters 2221 and 2223 and the receiver 2222 may be connected to the electrodes X1 to X6, X1′ to X6′, and Y1 to Y10 through the routing lines 2231 to 2233. For example, the transmitter 2221 may be connected to the routing line 2231, the receiver 2222 may be connected to the routing line 2232, and the transmitter 2223 may be connected to the routing line 2233. In other words, the transmitters 2221 and 2223 may transmit driving signals to the plurality of driving electrodes X1 to X6 and X1′ to X6′ through the routing lines 2231 and 2233. The receiver 2222 may receive sensing signals from the plurality of receiving electrodes Y1 to Y10 through the routing line 2232.

In the display module 2200 according to the embodiment, the touch sensor controller may be disposed on one side of the display driver circuit to improve the wiring connectivity of the touch screen panel 2210 and lower the die height of the touch screen driver circuit 2220. Accordingly, the number of dies for the touch screen driver circuit 2220 that can be obtained from one wafer can increase.

The display module 2200 may include the transmission lines for dual routing, which can reduce the resistance of wiring. Accordingly, the time constant can decrease, and the settling time can shorten. Further, in the display module 2200, the transmitters 2221 and 2223 and the receiver 2222 may be disposed on one side of the display driver circuit, which can reduce the wiring area of the routing lines 2231 to 2233, resulting in a decrease in the module size.

In some embodiments, the display module 2200 may further include shielding members between the transmitters 2221 and 2223 and the receiver 2222 or between the transmission lines and the reception line. The shielding members are members for preventing electromagnetic interference, and may include shielding lines, shielding layers, and the like.

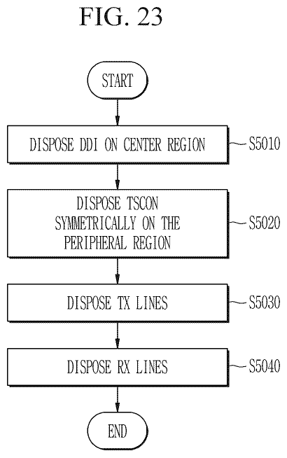

FIG. 23 is the flow chart of a method of manufacturing a display module according to one or more embodiments.

Referring to FIG. 23, a method of manufacturing a display module according to one or more embodiments may include an operation of disposing a display driver circuit (DDI) at the center region (S5010). The display driver circuit (DDI) may generate and transmit a source signal such that a display panel displays an image.

The method of manufacturing the display module may include an operation of disposing a first transmitter and receiver set and a second transmitter and receiver set symmetrically on the peripheral region (S5020). The first transmitter and receiver set and the second transmitter and receiver set may be included in a touch sensor controller (TSCON). Each transmitter and receiver set may include at least one transmitter and at least one receiver. The touch sensor controller (TSCON) may generate touch coordinates based on an input on a touch screen panel.

As an example, a first transmitter, a first receiver, and a second transmitter may be sequentially disposed in the left direction from the center region, and a third transmitter, a second receiver, and a fourth transmitter may be sequentially disposed in the right direction from the center region.

As an example, a first transmitter and a first receiver may be sequentially disposed in the left direction from the center region, and a second transmitter and a second receiver may be sequentially disposed in the right direction from the center region.

As an example, a first receiver and a first transmitter may be sequentially disposed in the left direction from the center region, and a second receiver and a second transmitter may be sequentially disposed in the right direction from the center region.

The touch sensor controller (TSCON) may further include a clock generator, a voltage generator, a touch processor, and the like.

The method of manufacturing the display module may include an operation of disposing transmission lines to connect the transmitters and driving electrodes (S5030). For example, the transmission lines may be disposed in a single routing or dual routing manner. When the transmission lines are implemented by single routing, the length of one driving electrode may correspond to the length of the touch screen panel (for example, the longitudinal length). When the transmission lines are implemented by dual routing, the length of one driving electrode may correspond to half the length of the touch screen panel.

The method of manufacturing the display module may include an operation of disposing reception lines to connect the receivers and receiving electrodes, so as not to intersect the transmission lines (S5040). In one or more embodiments, first reception lines that extend from the left side of the touch screen panel so as to be connected to left receivers, and second reception lines that extend from the right side of the touch screen panel so as to be connected to right receivers may be disposed. In some embodiments, when the touch sensor controller (TSCON) includes receivers only on the left side (or the right side), reception lines may be disposed only on the left side (or the right side) of the touch screen panel.

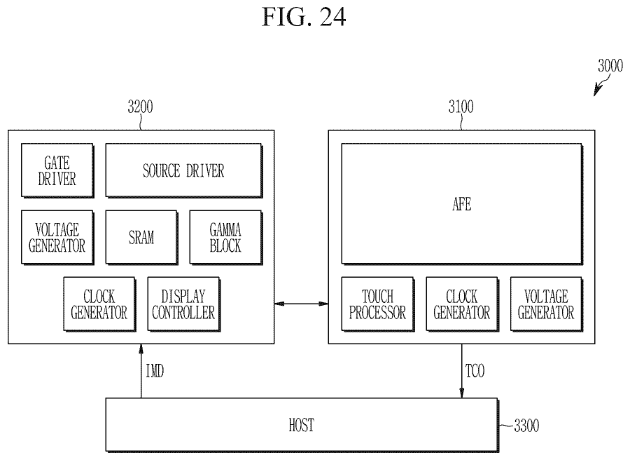

FIG. 24 is a block diagram of an electronic device according to one or more embodiments.

Referring to FIG. 24, an electronic device 3000 according to one or more embodiments may include a touch sensor controller 3100, a display driver circuit (DDI) 3200, and a host 3300. In some embodiments, the touch sensor controller 3100 and the DDI 3200 may be integrated in a single semiconductor chip, or may be implemented separately in a plurality of semiconductor chips.

The touch sensor controller 3100 and the DDI 3200 may operate under the control of the host 3300, and the DDI 3200 may receive an input image signal IMD from the host 3300 and drive a display panel (the reference symbol “120” in FIG. 1) such that an image according to the input image signal IMD is displayed on the display panel 120.

The touch sensor controller 3100 may scan a touch sensor (the reference symbol “110” in FIG. 1) and determine touch coordinates TCO based on sensing signals received from the touch sensor 110. The touch sensor controller 3100 may provide the touch coordinates TCO to the host 3300.

The touch sensor controller 3100 may include an analog front end (AFE), a touch processor, a clock generator, and a voltage generator. In addition, the touch sensor controller 3100 may include interface circuits for communication with the DDI 3200 and the host 3300.

The interface circuit for communication with the DDI 3200 may be implemented in one of universal asynchronous receiver transmitter (UART) interface, inter-integrated circuit (I2C) interface, improved inter-integrated circuit (I3C) interface, serial peripheral interface (SPI), mobile industry processor interface (MIPI), embedded display port (eDP) interface manners, but is not limited thereto.

The interface circuit for communication with the host 3300 may be implemented as one of various interfaces, such as an universal serial bus (USB) interface, a universal flash storage (UFS) interface, a multimedia controller (MMC) interface, an embedded MMC (eMMC) interface, a peripheral component interconnect express (PCIe) interface, an advanced technology attachment (ATA) interface, a serial advanced technology attachment (SATA) interface, a parallel advanced technology attachment (PATA) interface, a small computer system interface (SCSI), a serial attached SCSI (SAS), an enhanced small disk interface (ESDI), an integrated drive electronics (IDE) interface, a high-speed serial Interface, etc.

The clock generator may generate a clock signal to be used inside the touch sensor controller 3100, and the voltage generator may generate voltages to be used in the AFE.

The AFE may include the receiver 360 described with reference to FIG. 4, and the description of FIG. 4 may be equally applied. In other words, the AFE may receive sensing signals from the receiving electrodes, and receive a reference signal from a reference signal generator. The AFE may generate touch signals by removing noise signals from the sensing signals on the basis of the reference signal. The AFE may transmit the touch signals to the touch processor.

The touch processor may control the overall operation of the touch sensor controller. In other words, the touch processor may generate driving signals and transmit them to the transmitters. The touch processor may receive touch signals from the AFE, and generate touch data based on the touch signals. The touch processor may determine the touch coordinates TCO based on the touch data.

The DDI 3200 may include a clock generator, a display controller, a voltage generator, a gamma block, a static random access memory (SRAM), a gate driver, and a source driver. In addition, the DDI 3200 may include interface circuits for communication with the touch sensor controller 3100 and the host 3300.

The clock generator may generate clock signals to be used inside the DDI 3200, for example, clock signals to be provided to the source driver and the gate driver. The voltage generator may generate voltages to be used in the gate driver and the source driver, and the gamma block may generate a plurality of grayscale voltages corresponding to a plurality of grayscales that pixel values may have, and provide them to the source driver. The SRAM may store input image signals IMD received from the host 3300, and provide the input image signals IMD to the source driver on a line-by-line basis. For example, the SRAM may store the input image signals IMD in units of a plurality of lines, or may store an input image signal IMD of one frame.

The gate driver may provide gate signals (scan signals) to a plurality of gate lines (scan lines) provided in the display panel (the reference symbol “120” in FIG. 1) in turn, and the source driver may provide source signals to a plurality of source lines (data lines) provided in the display panel 120 simultaneously.

The display controller may control the overall operation of the DDI 3200. The display controller may control the gate driver, the source driver, the gamma block, and the like.

The touch sensor controller 3100 and the DDI 3200 may be manufactured as a single semiconductor module. The DDI 3200 may be disposed in the center of the semiconductor module, and the touch sensor controller 3100 may be disposed on the periphery of the DDI 3200 in the semiconductor module.

The semiconductor module may be connected to the touch sensor (or the touch screen panel) by a plurality of routing lines. For example, the touch sensor controller 3100 and the touch sensor may be connected to each other by a plurality of routing lines. In this case, of the plurality of routing lines, lines that are connected to the driving electrodes of the touch sensor may be referred to as transmission lines, and lines that are connected to the receiving electrodes may be referred to as reception lines. The transmission lines may be implemented by single routing or dual routing. The receiving electrodes may be implemented so as to transmit sensing signals to the AFE by single routing. In some embodiments, the AFE may be disposed on one side of the semiconductor module, or may be distributedly disposed on both sides.

The touch sensor controller 3100 and the DDI 3200 may perform communication with each other inside the electronic device 3000, and each of the touch sensor controller 3100 and the DDI 3200 may have ports for communication with each other, for example, a first port and a second port. Clock signals, voltages, data, and the like may be transmitted and received through data lines connected through the first port and the second port.

In some embodiments, each of the components described with reference to FIG. 1 to FIG. 24, or a combination of two or more components may be implemented as a digital circuit, a programmable or non-programmable logic device or array, an application specific integrated circuit (ASIC), etc.

While certain example embodiments the disclosure have been particularly shown and described, it will be understood that various changes in form and details may be made therein without departing from the spirit and scope of the following claims.

What is claimed is:

1. A semiconductor module comprising:
a display driver circuit configured to drive a display panel;
a touch sensor controller configured to generate touch coordinates based on an input on a touch screen panel, the touch sensor controller comprising:
a first transmitter and receiver set on a first side of the display driver circuit; and
a second transmitter and receiver set on a second side of the display driver circuit, the second side being opposite the first side; and
a plurality of routing lines connecting the touch sensor controller and the touch screen panel.

2. The semiconductor module of claim 1, wherein the touch screen panel comprises:
a plurality of driving electrodes arranged in a first direction and extending in a second direction intersecting the first direction; and
a plurality of receiving electrodes arranged in the second direction and extending in the first direction, each of the plurality of receiving electrodes having a length that is shorter than a length of each of the plurality of driving electrodes.

3. The semiconductor module of claim 2, wherein the first transmitter and receiver set and the second transmitter and receiver set are disposed symmetrically with respect to the display driver circuit.

4. The semiconductor module of claim 3, wherein the first transmitter and receiver set comprises a first transmitter, a first receiver, and a second transmitter sequentially aligned along the second direction with the display driver circuit,
wherein the second transmitter and receiver set comprises a third transmitter, a second receiver, and a fourth transmitter sequentially aligned along the second direction with the display driver circuit, and
wherein the plurality of routing lines comprises:
first transmission lines connected to first driving electrodes on a near side of the touch screen panel nearest to the touch sensor controller, the first transmission lines connecting the first transmitter and the first driving electrodes;
second transmission lines connected to second driving electrodes on the near side of the touch screen panel, the second transmission lines connecting the third transmitter and the second driving electrodes;
third transmission lines connected to third driving electrodes on a far side of the touch screen panel furthest from the touch sensor controller, the third transmission lines connecting the second transmitter and the third driving electrodes;
fourth transmission lines connected to fourth driving electrodes on the far side of the touch screen panel, the fourth transmission lines connecting the fourth transmitter and the fourth driving electrodes;
first reception lines connected to first receiving electrodes on a first side of the touch screen panel, the first reception lines connecting the first receiver and the first receiving electrodes, the first side of the touch screen panel being adjacent to the far side of the touch screen panel; and
second reception lines connected to second receiving electrodes on a second side of the touch screen panel, the second reception lines connecting the second receiver and the second receiving electrodes, the second side of the touch screen panel being opposite the first side of the touch screen panel.

5. The semiconductor module of claim 4, wherein the first reception lines contact the first receiving electrodes, and the first receiving electrodes are consecutively disposed closer to the far side of the touch screen panel than to the near side of the touch screen panel, and
wherein the second reception lines contact the second receiving electrodes, and the second receiving electrodes are the plurality of receiving electrodes other than the first receiving electrodes.

6. The semiconductor module of claim 4, wherein the first reception lines contact the first receiving electrodes, and the first receiving electrodes are consecutively disposed closer to the near side of the touch screen panel than to the far side of the touch screen panel, and
wherein the second reception lines contact the second receiving electrodes, and the second reception lines are the plurality of receiving electrodes other than the first receiving electrodes.

7. The semiconductor module of claim 4,
wherein the first reception lines contact the first receiving electrodes, and the first receiving electrodes are even-numbered electrodes among the plurality of receiving electrodes in the touch screen panel, and
wherein the second reception lines contact the second receiving electrodes, and the second receiving electrodes are odd-numbered electrodes among the plurality of receiving electrodes in the touch screen panel.

8. The semiconductor module of claim 3, wherein the first transmitter and receiver set comprises a first transmitter and a first receiver sequentially disposed on the first side of the display driver circuit,
wherein the second transmitter and receiver set comprises a second transmitter and a second receiver sequentially disposed on the second side of the display driver circuit, and
wherein the plurality of routing lines comprises:
first transmission lines connected to first driving electrodes on a near side of the touch screen panel nearest to the touch sensor controller, the first transmission lines connecting the first transmitter and the first driving electrodes;
second transmission lines connected to second driving electrodes on the near side of the touch screen panel, the second transmission lines connecting the second transmitter and the second driving electrodes;
first reception lines connected to first receiving electrodes on a first side of the touch screen panel, the first reception lines connecting the first receiver and the first receiving electrodes, the first side of the touch screen panel being adjacent to the far side of the touch screen panel; and
second reception lines connected to second receiving electrodes on a second side of the touch screen panel, the second reception lines connecting the second receiver and the second receiving electrodes, the second side of the touch screen panel being opposite the first side of the touch screen panel.

9. The semiconductor module of claim 1, wherein the first transmitter and receiver set comprises a first transmitter and a first receiver aligned with the display driver circuit in a direction,
wherein the second transmitter and receiver set comprises a second receiver and a second transmitter aligned with the display driver circuit in the direction, and
wherein the plurality of routing lines comprises:
first transmission lines connected to first driving electrodes on a near side of the touch screen panel nearest to the touch sensor controller, the first transmission lines connecting the first transmitter and the first driving electrodes;
second transmission lines connected to second driving electrodes on a far side of the touch screen panel furthest from the touch sensor controller, the second transmission lines connecting the second transmitter and the second driving electrodes;
first reception lines connected to first receiving electrodes on a first side of the touch screen panel, the first reception lines connecting the first receiver and the first receiving electrodes, the first side of the touch screen panel being adjacent to the far side of the touch screen panel; and
second reception lines connected to second receiving electrodes on a second side of the touch screen panel, the second reception lines connecting the second receiver and the second receiving electrodes, the second side of the touch screen panel being opposite the first side of the touch screen panel.

10. The semiconductor module of claim 1, wherein the first transmitter and receiver set comprises a first receiver and a first transmitter aligned with the display driver circuit in a direction,
wherein the second transmitter and receiver set comprises a second transmitter and a second receiver aligned with the display driver circuit in the direction, and
wherein the plurality of routing lines comprises:
first transmission lines connected to first driving electrodes on a far side of the touch screen panel furthest from the touch sensor controller, the first transmission lines connecting the first transmitter and the first driving electrodes;
second transmission lines connected to second driving electrodes on a near side of the touch screen panel nearest to the touch sensor controller, the second transmission lines connecting the second transmitter and the second driving electrodes;
first reception lines connected to first receiving electrodes on a first side of the touch screen panel, the first reception lines connecting the first receiver and the first receiving electrodes, the first side of the touch screen panel being adjacent to the far side of the touch screen panel; and
second reception lines that are connected to second receiving electrodes on a second side of the touch screen panel, the second reception lines connecting the second receiver and the second receiving electrodes, the second side of the touch screen panel being opposite the first side of the touch screen panel.

11. The semiconductor module of claim 1, further comprising:
a shielding member between a transmitter and a receiver of the touch sensor controller.

12. The semiconductor module of claim 1, wherein the display panel is an organic light emitting diode (OLED) display, and
wherein the display driver circuit comprises:
a gamma voltage generator configured to generate a plurality of gamma voltages; and
a source driver configured to:
generate a plurality of source signals corresponding to an input image signal based on the plurality of gamma voltages; and
transmit the plurality of source signals to the display panel through a plurality of source lines.

13. A semiconductor module comprising:
a display driver circuit configured to drive a display panel;
a touch sensor controller configured to generate touch coordinates based on an input on a touch screen panel, and comprising:
first receivers and second receivers on both sides of the display driver circuit, respectively; and
transmitters on one side of the display driver circuit; and
a plurality of routing lines connecting the touch sensor controller and the touch screen panel.

14. The semiconductor module of claim 13, wherein the plurality of routing lines comprises transmission lines for single routing that contact driving electrodes on a lower side of the touch screen panel.

15. The semiconductor module of claim 13, wherein the plurality of routing lines comprises transmission lines for single routing that contact driving electrodes on an upper side of the touch screen panel.

16. The semiconductor module of claim 13, wherein the transmitters are between the first receivers and the display driver circuit, or are between the second receivers and the display driver circuit.

17. The semiconductor module of claim 13, wherein the touch sensor controller comprises fewer transmitters than numbers of the first receivers and the second receivers, and
wherein the plurality of routing lines comprises:
reception lines corresponding to the first receivers and the second receivers; and
transmission lines corresponding to the transmitters.

18. A display device comprising:
a display panel comprising a plurality of pixels and a plurality of source lines connected to the plurality of pixels;
a plurality of first direction touch electrodes and a plurality of second direction touch electrodes;
a plurality of routing lines connected to the plurality of first direction touch electrodes and the plurality of second direction touch electrodes; and
a touch screen driver circuit comprising:
a display driver circuit disposed on a center region of the touch screen driver circuit, and configured to apply a plurality of source signals to the plurality of source lines; and
a transmitter and receiver set on a periphery of the center region and connected to the plurality of routing lines.

19. The display device of claim 18, wherein the plurality of first direction touch electrodes comprises:
first driving electrodes on a first region; and
second driving electrodes on a second region closer to the touch screen driver circuit than the first region in a first direction, and
wherein the plurality of routing lines comprises:
first transmission lines connected to the first driving electrodes; and
second transmission lines connected to the second driving electrodes.

20. The display device of claim 18, wherein the display panel is an organic light emitting diode (OLED) display, and
wherein the plurality of first direction touch electrodes and the plurality of second direction touch electrodes comprise rhombic unit electrodes intersecting each other.
